(19) United States
(12) Patent Application Publication
(10) Pub. No.: US 2026/0260680 A1
(43) Pub. Date: Sep. 3, 2026

(54) STORAGE DEVICE

(71) Applicant: SONY SEMICONDUCTOR SOLUTIONS CORPORATION, KANAGAWA (JP)

(72) Inventors: LUI SAKAI, KANAGAWA (JP); KEIZO HIRAGA, KANAGAWA (JP); YUTAKA HIGO, KANAGAWA (JP); MASANORI HOSOMI, KANAGAWA (JP)

(21) Appl. No.: 18/997,212

(22) PCT Filed: Jun. 5, 2023
(86) PCT No.: PCT/JP2023/020838

§ 371 Date: Jan. 21, 2025

(30) Foreign Application Priority Data
Aug. 2, 2022 (JP) 2022-123051

(51) Int. Cl. G11C 11/16; H10N 50/10; H10N 50/85

(52) U.S. Cl. CPC G11C 11/1697; G11C 11/161; G11C 11/1659; G11C 11/1675; H10N 50/10; H10N 50/85

(57) ABSTRACT

It is enabled to store data held in a volatile storage unit in a nonvolatile storage unit on the basis of voltage drive. A storage device includes: a volatile storage unit that complementarily holds data; and a voltage-controlled magneto-resistive effect element that holds the data complementarily held in the volatile storage unit. There may be further included a variable resistance element connected between the volatile storage unit and the voltage-controlled magneto-resistive effect element, the variable resistance element enabling resistance between the volatile storage unit and the voltage-controlled magneto-resistive effect element to vary. The variable resistance element may vary resistance to cause cell voltages applied to the voltage-controlled magneto-resistive effect element to be substantially equal to each other, the cell voltages being a cell voltage applied when the voltage-controlled magneto-resistive effect element transitions from a high resistance state to a low resistance state and a cell voltage applied when the voltage-controlled magneto-resistive effect element transitions from the low resistance state to the high resistance state.

### TECHNICAL FIELD

The present technology relates to a storage device. More particularly, the present technology relates to a storage device in which a nonvolatile storage unit is provided in a volatile storage unit.

### BACKGROUND ART

There is a storage device in which a nonvolatile storage unit is added to a memory cell provided with a volatile storage unit in order to prevent data held in the volatile storage unit from being lost even when a power supply abnormality or a power supply interruption occurs. As such a storage device, for example, there is a configuration including a bistable circuit that stores data and nonvolatile elements that store data stored in the bistable circuit in a nonvolatile manner and restore the data stored in the nonvolatile manner in the bistable circuit (see, for example, Patent Document 1).

### CITATION LIST

### Patent Document

Patent Document 1: WO 2013/172066 A

### SUMMARY OF THE INVENTION

### Problems to be Solved by the Invention

However, in the above-described conventional technology, in a case where data is to be stored in the nonvolatile elements, the nonvolatile elements are driven by currents, and currents in opposite directions from each other have been caused to flow in the nonvolatile elements according to the data to be stored. For this reason, depending on the nonvolatile elements, the currents flowing at the time of storing data may increase, leading to an increase in power consumption.

The present technology has been made in view of such a situation, and an object of the present technology is to enable data held in a volatile storage unit to be stored in a nonvolatile storage unit on the basis of voltage drive.

### Solutions to Problems

The present technology has been made to solve the above-described problem, and a first aspect thereof is a storage device including: a volatile storage unit that complementarily holds data; and a voltage-controlled magneto-resistive effect element that holds the data complementarily held in the volatile storage unit. This brings about an effect that data held in the volatile storage unit is stored in the nonvolatile storage unit on the basis of voltage drive.

Furthermore, in the first aspect, there may be further included a variable resistance element connected between the volatile storage unit and the voltage-controlled magneto-resistive effect element, the variable resistance element enabling resistance between the volatile storage unit and the voltage-controlled magneto-resistive effect element to vary. This brings about an effect that the voltage-controlled magneto-resistive effect element is transitioned from a high resistance state to a low resistance state while maintaining the low resistance state at the time of low resistance writing, and is transitioned from the low resistance state to the high resistance state while maintaining the high resistance state at the time of high resistance writing.

Furthermore, in the first aspect, the variable resistance element may vary resistance to cause cell voltages applied to the voltage-controlled magneto-resistive effect element to be substantially equal to each other, the cell voltages being a cell voltage applied when the voltage-controlled magneto-resistive effect element transitions from a high resistance state to a low resistance state and a cell voltage applied when the voltage-controlled magneto-resistive effect element transitions from the low resistance state to the high resistance state. This brings about an effect that data is written to the voltage-controlled magneto-resistive effect element on the basis of the cell voltage having the same polarity applied to the voltage-controlled magneto-resistive effect element.

Furthermore, in the first aspect, the variable resistance element may be a field effect transistor whose on-resistance varies on the basis of a gate voltage. This brings about an effect that the cell voltages applied to the voltage-controlled magneto-resistive effect element are equal to each other, the cell voltages being a cell voltage when the voltage-controlled magneto-resistive effect element transitions from the high resistance state to the low resistance state and a cell voltage when the voltage-controlled magneto-resistive effect element transitions from the low resistance state to the high resistance state.

Furthermore, in the first aspect, the field effect transistor may be used not only as the variable resistance element but also as a storing transistor that stores data from the volatile storage unit to the voltage-controlled magneto-resistive effect element and a restoring transistor that restores the data from the voltage-controlled magneto-resistive effect element to the volatile storage unit. This brings about an effect that it is possible to perform storing and restoring between the voltage-controlled magneto-resistive effect element and the volatile storage unit while achieving simplification of a circuit configuration.

Furthermore, in the first aspect, there may be further included a gate voltage switching unit that switches between a first gate voltage applied to the field effect transistor in a case where low resistance writing is performed for the voltage-controlled magneto-resistive effect element and a second gate voltage applied to the field effect transistor in a case where high resistance writing is performed for the voltage-controlled magneto-resistive effect element. This brings about an effect that writing of the low resistance state and the high resistance state of the voltage-controlled magneto-resistive effect element is performed on the basis of switching of the gate voltage.

Furthermore, in the first aspect, in a case where the voltage-controlled magneto-resistive effect element is in a high resistance state in the case where low resistance writing is performed, a reversal voltage that reverses a magnetization direction of the voltage-controlled magneto-resistive effect element may be applied to the voltage-controlled magneto-resistive effect element on the basis of the first gate voltage; in a case where the voltage-controlled magneto-resistive effect element is in a low resistance state in the case where low resistance writing is performed, a voltage smaller than the reversal voltage may be applied to the voltage-controlled magneto-resistive effect element on the basis of the first gate voltage; in a case where the voltage-controlled magneto-resistive effect element is in the low resistance state in the case where high resistance writing is performed, the reversal voltage may be applied to the voltage-controlled magneto-resistive effect element on the basis of the second gate voltage; and in a case where the voltage-controlled magneto-resistive effect element is in the high resistance state in the case where high resistance writing is performed, a voltage larger than the reversal voltage may be applied to the voltage-controlled magneto-resistive effect element on the basis of the second gate voltage. This brings about an effect that data is written complementarily to the voltage-controlled magneto-resistive effect element on the basis of the cell voltage having the same polarity applied to the voltage-controlled magneto-resistive effect element.

Furthermore, in the first aspect, there may be further included a voltage driver that applies a reversal voltage that reverses a magnetization direction of the voltage-controlled magneto-resistive effect element on the basis of a voltage controlled magnetic anisotropy (VCMA) effect. This brings about an effect that data is written to the voltage-controlled magneto-resistive effect element on the basis of the VCMA effect.

Furthermore, in the first aspect, in the voltage-controlled magneto-resistive effect element, a low resistance state and a high resistance state according to the data complementarily held in the volatile storage unit may be each stored on the basis of stepwise change in voltage having an identical polarity applied to the voltage-controlled magneto-resistive effect element. This brings about an effect that the low resistance state and the high resistance state each are stored in the voltage-controlled magneto-resistive effect element on the basis of the cell voltage having the same polarity applied to the voltage-controlled magneto-resistive effect element.

Furthermore, in the first aspect, the voltage-controlled magneto-resistive effect element may include a first voltage-controlled magneto-resistive effect element and a second voltage-controlled magneto-resistive effect element in which resistance states different from each other are set in accordance with the data complementarily held in the volatile storage unit; the voltage driver may apply, to the first voltage-controlled magneto-resistive effect element and the second voltage-controlled magneto-resistive effect element, a first drive voltage and then a second drive voltage in accordance with node voltages corresponding to the data complementarily held in the volatile storage unit; the first drive voltage may be set to cause a reversal voltage to be applied to the first voltage-controlled magneto-resistive effect element and perpendicular magnetic anisotropy of the second voltage-controlled magneto-resistive effect element to be increased; and the second drive voltage may be set to cause a reversal voltage to be applied to the second voltage-controlled magneto-resistive effect element, and a voltage smaller than the reversal voltage to be applied to the first voltage-controlled magneto-resistive effect element. This brings about an effect that data is written to the second voltage-controlled magneto-resistive effect element on the basis of the second drive voltage without destroying data written to the first voltage-controlled magneto-resistive effect element on the basis of the first drive voltage.

Furthermore, in the first aspect, when the reversal voltage is applied to the first voltage-controlled magneto-resistive effect element, a voltage higher than the reversal voltage by a difference between the node voltages may be applied to the second voltage-controlled magneto-resistive effect element, and when the reversal voltage is applied to the second voltage-controlled magneto-resistive effect element, a voltage lower than the reversal voltage by the difference between the node voltages may be applied to the first voltage-controlled magneto-resistive effect element. This brings about an effect that data is written to the second voltage-controlled magneto-resistive effect element without destroying data written to the first voltage-controlled magneto-resistive effect element in accordance with the node voltages corresponding to the data complementarily held in the volatile storage unit.

Furthermore, in the first aspect, the voltage smaller than the reversal voltage may be 0 V. This brings about an effect that reversal of the magnetization direction of the first voltage-controlled magneto-resistive effect element is prevented when data is written to the second voltage-controlled magneto-resistive effect element.

Furthermore, in the first aspect, the voltage-controlled magneto-resistive effect element may include: a pinned layer in which a magnetization direction is fixed; a free layer in which a magnetization direction of magnetism induced on the basis of a voltage is reversible; and a tunnel barrier layer sandwiched between the pinned layer and the free layer. This brings about an effect that the magnetization direction of the voltage-controlled magneto-resistive effect element is reversed on the basis of voltage drive.

Furthermore, in the first aspect, in a case where data is stored from the volatile storage unit to the voltage-controlled magneto-resistive effect element, the first drive voltage may be applied to the free layer of the voltage-controlled magneto-resistive effect element when the first gate voltage is applied to the field effect transistor, and then the second drive voltage may be applied to the free layer of the voltage-controlled magneto-resistive effect element when the second gate voltage is applied to the field effect transistor, and in a case where the data is restored from the voltage-controlled magneto-resistive effect element to the volatile storage unit, a voltage lower than a voltage applied to the pinned layer may be applied to the free layer. This brings about an effect that high resistance writing is performed after low resistance writing without destroying the low resistance state at the time of low resistance writing.

Furthermore, in the first aspect, in a case where data is stored from the volatile storage unit to the voltage-controlled magneto-resistive effect element, the first drive voltage may be applied to the free layer of the voltage-controlled magneto-resistive effect element when the second gate voltage is applied to the field effect transistor, and then the second drive voltage may be applied to the free layer of the voltage-controlled magneto-resistive effect element when the first gate voltage is applied to the field effect transistor, and in a case where the data is restored from the voltage-controlled magneto-resistive effect element to the volatile storage unit, a voltage higher than a voltage applied to the pinned layer may be applied to the free layer. This brings about an effect that low resistance writing is performed after high resistance writing without destroying the high resistance state at the time of high resistance writing, and a voltage is applied at the time of restoring so that the perpendicular magnetic anisotropy increases.

Furthermore, in the first aspect, in a case where data is stored from the volatile storage unit to the voltage-controlled magneto-resistive effect element, the first drive voltage may be applied to the pinned layer of the voltage-controlled magneto-resistive effect element when the second gate voltage is applied to the field effect transistor, and then the second drive voltage may be applied to the pinned layer of the voltage-controlled magneto-resistive effect element when the first gate voltage is applied to the field effect transistor, and in a case where the data is restored from the voltage-controlled magneto-resistive effect element to the volatile storage unit, a voltage lower than a voltage applied to the free layer may be applied to the pinned layer. This brings about an effect that while high resistance writing is enabled with no negative voltage, low resistance writing is performed after high resistance writing without destroying the high resistance state at the time of high resistance writing, and a voltage is applied at the time of restoring so that the perpendicular magnetic anisotropy increases.

Furthermore, in the first aspect, in a case where data is stored from the volatile storage unit to the voltage-controlled magneto-resistive effect element, the first drive voltage may be applied to the pinned layer of the voltage-controlled magneto-resistive effect element when the first gate voltage is applied to the field effect transistor, and then the second drive voltage may be applied to the pinned layer of the voltage-controlled magneto-resistive effect element when the second gate voltage is applied to the field effect transistor, and in a case where the data is restored from the voltage-controlled magneto-resistive effect element to the volatile storage unit, a voltage higher than a voltage applied to the free layer may be applied to the pinned layer. This brings about an effect that while low resistance writing is enabled with no negative voltage, high resistance writing is performed after low resistance writing without destroying the low resistance state at the time of low resistance writing.

Furthermore, in the first aspect, the volatile storage unit may be a latch circuit. This brings about an effect that a nonvolatile storage function is added to the latch circuit.

Furthermore, in the first aspect, the volatile storage unit may be a flip-flop. This brings about an effect that a nonvolatile storage function is added to the flip-flop.

Furthermore, in the first aspect, the volatile storage unit may be a static random access memory (SRAM). This brings about an effect that a nonvolatile storage function is added to the SRAM.

### BRIEF DESCRIPTION OF DRAWINGS

FIG. 1 is a diagram illustrating a configuration example of a storage device according to a first embodiment.

FIG. 2 is a diagram illustrating an example of latch operation of the storage device according to the first embodiment.

FIG. 3 is a diagram illustrating an example of first storing operation of the storage device according to the first embodiment.

FIG. 4 is a diagram illustrating an example of second storing operation and restoring operation of the storage device according to the first embodiment.

FIG. 5 is a timing chart illustrating an example of a storing timing of the storage device according to the first embodiment.

FIG. 6 is a timing chart illustrating an example of the restoring timing of the storage device according to the first embodiment.

FIG. 7 is a diagram illustrating a configuration example of a storage device according to a second embodiment.

FIG. 8 is a diagram illustrating an example of the latch operation of the storage device according to the second embodiment.

FIG. 9 is a diagram illustrating an example of the first storing operation of the storage device according to the second embodiment.

FIG. 10 is a diagram illustrating an example of the second storing operation of the storage device according to the second embodiment.

FIG. 11 is a diagram illustrating an example of the restoring operation of the storage device according to the second embodiment.

FIG. 12 is a timing chart illustrating an example of the storing timing of the storage device according to the second embodiment.

FIG. 13 is a timing chart illustrating an example of the restoring timing of the storage device according to the second embodiment.

FIG. 14 is a diagram illustrating a configuration example of a storage device according to a third embodiment.

FIG. 15 is a diagram illustrating an example of the latch operation of the storage device according to the third embodiment.

FIG. 16 is a diagram illustrating an example of the first storing operation of the storage device according to the third embodiment.

FIG. 17 is a diagram illustrating an example of the second storing operation of the storage device according to the third embodiment.

FIG. 18 is a diagram illustrating an example of the restoring operation of the storage device according to the third embodiment.

FIG. 19 is a timing chart illustrating an example of the storing timing of the storage device according to the third embodiment.

FIG. 20 is a timing chart illustrating an example of the restoring timing of the storage device according to the third embodiment.

FIG. 21 is a diagram illustrating a configuration example of a storage device according to a fourth embodiment.

FIG. 22 is a diagram illustrating an example of the first storing operation of the storage device according to the fourth embodiment.

FIG. 23 is a diagram illustrating an example of the second storing operation of the storage device according to the fourth embodiment.

FIG. 24 is a diagram illustrating an example of the restoring operation of the storage device according to the fourth embodiment.

FIG. 25 is a timing chart illustrating an example of the storing timing of the storage device according to the fourth embodiment.

FIG. 26 is a timing chart illustrating an example of the restoring timing of the storage device according to the fourth embodiment.

FIG. 27 is a diagram illustrating a configuration example of a storage device according to a fifth embodiment.

FIG. 28 is a diagram illustrating a modification of the storage device according to the fifth embodiment.

FIG. 29 is a block diagram illustrating an overall configuration example of a storage device according to a sixth embodiment.

FIG. 30 is a diagram illustrating a configuration example of a memory cell of the storage device according to the sixth embodiment.

### MODE FOR CARRYING OUT THE INVENTION

Modes for carrying out the present technology (hereinafter, referred to as embodiments) will be described below. The description will be given in the following order.
1. First Embodiment (example in which voltage-controlled magneto-resistive effect element is provided in latch circuit, drive voltage is applied to free layer of voltage-controlled magneto-resistive effect element, and forward logic of latch circuit is stored in voltage-controlled magneto-resistive effect element)
2. Second Embodiment (example in which voltage-controlled magneto-resistive effect element is provided in latch circuit, drive voltage is applied to free layer of voltage-controlled magneto-resistive effect element, and inverse logic of latch circuit is stored in voltage-controlled magneto-resistive effect element)
3. Third Embodiment (example in which voltage-controlled magneto-resistive effect element is provided in latch circuit, drive voltage is applied to pinned layer of voltage-controlled magneto-resistive effect element, and forward logic of latch circuit is stored in voltage-controlled magneto-resistive effect element)
4. Fourth Embodiment (example in which voltage-controlled magneto-resistive effect element is provided in latch circuit, drive voltage is applied to pinned layer of voltage-controlled magneto-resistive effect element, and inverse logic of latch circuit is stored in voltage-controlled magneto-resistive effect element)
5. Fifth Embodiment (example in which voltage-controlled magneto-resistive effect element is provided in flip-flop)
6. Sixth Embodiment (example in which voltage-controlled magneto-resistive effect element is provided in SRAM)

### 1. First Embodiment

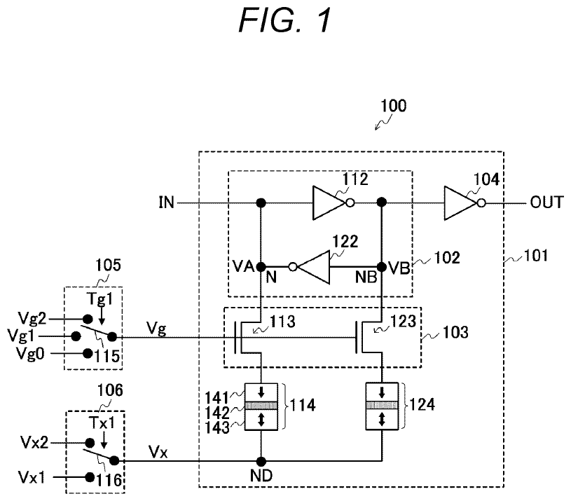

FIG. 1 is a diagram illustrating a configuration example of a storage device according to a first embodiment.

In the figure, a storage device 100 includes a latch cell 101, a gate voltage switching unit 105, and a voltage driver 106. The latch cell 101 includes a latch circuit 102, a variable resistance circuit 103, voltage-controlled magneto-resistive effect elements 114 and 124, and an inverter 104.

Note that the latch circuit 102 is an example of a volatile storage unit described in the claims. Each of the voltage-controlled magneto-resistive effect elements 114 and 124 is an example of a nonvolatile storage unit. At this time, the nonvolatile storage unit can hold, in a nonvolatile manner, data held in the volatile storage unit in a volatile manner. Furthermore, the nonvolatile storage unit can write the data held in a nonvolatile manner by the nonvolatile storage unit, back to the volatile storage unit. Note that, the term “volatile” as used herein means that power is required to hold data. Furthermore, the term “nonvolatile” as used herein means that no power is required to hold data.

Note that, in the present specification, processing of writing data held in the volatile storage unit to the nonvolatile storage unit is referred to as storing, and processing of writing data held in the nonvolatile storage unit back to the volatile storage unit is referred to as restoring.

The latch circuit 102 complementarily holds data. At this time, the latch circuit 102 operates as a bistable circuit and can hold the data in a volatile manner. The latch circuit 102 includes volatile storage nodes N and NB that complementarily hold the data. Each of the volatile storage nodes N and NB holds the data in a volatile manner. At this time, the latch circuit 102 can latch input data IN, complementarily hold a logical value corresponding to the input data IN in each of the volatile storage nodes N and NB, and output the logical value as output data OUT via the inverter 104. Note that, the term “complementary” as used herein refers to a relationship in which, when data ‘0’ is held in the volatile storage node N, data ‘1’ is held in the volatile storage node NB, and when data ‘1’ is held in the volatile storage node N, the data ‘0’ is held in the volatile storage node NB.

The latch circuit 102 includes inverters 112 and 122. Each of the inverters 112 and 122 can include a complementary metal oxide semiconductor (CMOS) transistor. For example, each of the inverters 112 and 122 may include a series connection of a PMOS transistor and an NMOS transistor.

The input of the inverter 112 is connected to the output of the inverter 122, and the input of the inverter 122 is connected to the output of the inverter 112. At this time, the volatile storage node N can be provided at a connection point between the input of the inverter 112 and the output of the inverter 122, and the volatile storage node NB can be provided at a connection point between the input of the inverter 122 and the output of the inverter 112.

Each of the voltage-controlled magneto-resistive effect elements 114 and 124 has a voltage controlled magnetic anisotropy (VCMA) effect. At this time, each of the voltage-controlled magneto-resistive effect elements 114 and 124 can operate as a voltage controlled magnetoresistive random access memory (VC-MRAM). Here, a resistance state of each of the voltage-controlled magneto-resistive effect elements 114 and 124 can take a low resistance state and a high resistance state. At this time, each of the voltage-controlled magneto-resistive effect elements 114 and 124 can transition between the low resistance state and the high resistance state by reversing a magnetization direction on the basis of the VCMA effect.

Each of the voltage-controlled magneto-resistive effect elements 114 and 124 includes a pinned layer 141, a tunnel barrier layer 142, and a free layer 143. The tunnel barrier layer 142 is sandwiched between the pinned layer 141 and the free layer 143. The pinned layers 141 of the voltage-controlled magneto-resistive effect elements 114 and 124 are connected to MOS transistors 113 and 123, respectively. The free layers 143 of the voltage-controlled magneto-resistive effect elements 114 and 124 are connected to a drive terminal ND.

The pinned layer 141 is a layer having magnetic anisotropy and an invariable magnetization direction. The pinned layer 141 can include, for example, CoFeB, CoFeC alloy, NiFeB alloy, NiFeC alloy, or the like. Furthermore, the pinned layer 141 may have a laminated ferri-pin structure in which a plurality of ferromagnetic layers is laminated with a nonmagnetic layer interposed therebetween. As a material of the ferromagnetic layer constituting a magnetization fixed layer having the laminated ferri-pin structure, Co, CoFe, CoFeB, or the like can be used. Furthermore, as a material of the nonmagnetic layer, Ru, Re, Ir, Os, or the like can be used.

The pinned layer 141 can have a configuration in which the magnetization direction is fixed by using an antiferromagnetic coupling between an antiferromagnetic layer and a ferromagnetic layer. Examples of the material of the antiferromagnetic layer include magnetic materials such as FeMn alloy, PtMn alloy, PtCrMn alloy, NiMn alloy, IrMn alloy, NiO, and Fe₂O₃.

Furthermore, a nonmagnetic element such as Ag, Cu, Au, Al, Si, Bi, Ta, B, C, O, N, Pd, Pt, Zr, Hf, Ir, W, Mo, or Nb can be added to these magnetic materials.

The tunnel barrier layer 142 applies an electric field to the free layer 143 to impart a voltage-controlled magnetic anisotropy effect. The tunnel barrier layer 142 can include an oxide of at least one element selected from a group of Mg, Al, Ti, Si, Zn, Zr, Hf, Ta, Bi, Cr, Ga, La, Gd, Sr, and Ba, or a nitride of at least one element selected from a group of Mg, Al, Ti, Si, Zn, Zr, Hf, Ta, Bi, Cr, Ga, La, Gd, Sr, and Ba. Furthermore, an insulator such as MgF₂, CaF, SrTiO₂, AlLaO₃, or AlNO, a dielectric, or a semiconductor may be used. Layers of these may be laminated. Note that a thickness of the tunnel barrier layer 142 is preferably greater than or equal to 0.6 nm.

The free layer 143 has magnetic anisotropy, and a magnetization direction of magnetism induced on the basis of a voltage can be reversed. Furthermore, the free layer 143 is a layer having the VCMA effect. A state in which the magnetization direction of the free layer 143 is the same as the magnetization direction of the pinned layer 141 and a state in which the magnetization directions are different from each other are referred to as a parallel state and an antiparallel state, respectively. Each of the voltage-controlled magneto-resistive effect elements 114 and 124 is in the low resistance state in the parallel state, and is in the high resistance state in the antiparallel state. The free layer 143 can change the magnetization direction on the basis of voltage application to each of the voltage-controlled magneto-resistive effect elements 114 and 124.

Furthermore, the free layer 143 can include cobalt iron (CoFe), cobalt iron boron (CoFeB), Fe, iron boride (FeB), or the like. Furthermore, the free layer 143 may contain a transition metal (Hf, Ta, VWe, Ir, Pt, Au, Zr, Nb, Mo, Ru, Rh, Pd, Ag, Ti, V, Cr, Mn, Ni, Cu) or the like. Furthermore, the free layer 143 may contain a nitride or an oxide. Furthermore, iridium (Ir) or osmium (Os) can be used as a material that induces proximity magnetic moment induction to the magnetic materials. Note that a heavy metal may be added to the free layer 143 to improve the VCMA effect. In order to cause each of the voltage-controlled magneto-resistive effect elements 114 and 124 to have the VCMA effect, a thickness of the free layer 143 is preferably less than or equal to 3.0 nm.

Furthermore, the free layer 143 may have a laminated structure in which a plurality of ferromagnetic layers is laminated with a nonmagnetic layer interposed therebetween. At this time, two ferromagnetic layers adjacent to each other with the nonmagnetic layer interposed therebetween may be exchange-coupled. The nonmagnetic layer can include Mg, Al, Ti, Si, Zn, Zr, Hf, Ta, Bi, Cr, Ga, La, Gd, Sr, Ba, VWe, Ir, Pt, Au, Nb, Mo, Ru, Rh, Pd, Ag, V, Mn, Ni, Cu, or the like.

Formation of the pinned layer 141, tunnel barrier layer 142, and free layer 143 may be performed by a physical vapor deposition (PVD) method such as a sputtering method, an ion beam deposition method, or a vacuum deposition method, an atomic layer deposition (ALD) method, or a chemical vapor deposition (CVD) method. Furthermore, a reactive ion etching (RIE) method or an ion milling method may be used for patterning the pinned layer 141, tunnel barrier layer 142, and free layer 143.

The variable resistance circuit 103 varies resistance to cause cell voltages to be substantially equal to each other, the cell voltages being a cell voltage when each of the voltage-controlled magneto-resistive effect elements 114 and 124 transitions from the high resistance state to the low resistance state and a cell voltage when each of the voltage-controlled magneto-resistive effect elements 114 and 124 transitions from the low resistance state to the high resistance state. Note that “substantially equal to each other” includes not only a case where two things are equal to each other but also a case where there is a deviation of about several percent. The cell voltage at this time is equal to a reversal voltage. The reversal voltage is a voltage that reverses the magnetization direction of each of the voltage-controlled magneto-resistive effect elements 114 and 124 on the basis of the VCMA effect. Reversal voltages are substantially equal to each other, the reversal voltages being a reversal voltage when each of the voltage-controlled magneto-resistive effect elements 114 and 124 transitions from the high resistance state to the low resistance state and a reversal voltage when each of the voltage-controlled magneto-resistive effect elements 114 and 124 transitions from the low resistance state to the high resistance state. When the reversal voltage is applied to each of the voltage-controlled magneto-resistive effect elements 114 and 124, perpendicular magnetic anisotropy of each of the voltage-controlled magneto-resistive effect elements 114 and 124 is zero. The variable resistance circuit 103 is disposed between each of the voltage-controlled magneto-resistive effect elements 114 and 124, and the latch circuit 102.

The variable resistance circuit 103 includes the MOS transistors 113 and 123. On-resistance of each of the MOS transistors 113 and 123 changes on the basis of a gate voltage Vg. The MOS transistor 113 is connected between the voltage-controlled magneto-resistive effect element 114 and the volatile storage node N. The MOS transistor 123 is connected between the voltage-controlled magneto-resistive effect element 124 and the volatile storage node NB. At this time, the MOS transistor 113 can be used not only as a variable resistance element but also as a storing transistor that stores data from the latch circuit 102 to the voltage-controlled magneto-resistive effect element 114 and a restoring transistor that restores the data from the voltage-controlled magneto-resistive effect element 114 to the latch circuit 102. Furthermore, the MOS transistor 123 can be used not only as a variable resistance element but also as a storing transistor that stores data from the latch circuit 102 to the voltage-controlled magneto-resistive effect element 124 and a restoring transistor that restores the data from the voltage-controlled magneto-resistive effect element 124 to the latch circuit 102. Note that the MOS transistors 113 and 123 are examples of a variable resistance element described in the claims.

The gate voltage switching unit 105 switches the gate voltage Vg among voltages Vg0, Vg1, and Vg2. The voltage Vg0 is set so that the MOS transistors 113 and 123 are turned off. The voltage Vg0 is, for example, a ground voltage. The voltage Vg1 is set so that the cell voltage is equal to the reversal voltage, the cell voltage being applied to each of the voltage-controlled magneto-resistive effect elements 114 and 124 in a case where low resistance writing is performed for each of the voltage-controlled magneto-resistive effect elements 114 and 124. The voltage Vg2 is set so that the cell voltage is equal to the reversal voltage, the cell voltage being applied to each of the voltage-controlled magneto-resistive effect elements 114 and 124 in a case where high resistance writing is performed for each of the voltage-controlled magneto-resistive effect elements 114 and 124. At this time, the gate voltage switching unit 105 switches the gate voltage Vg so that low resistance writing is performed at the time of storing and then high resistance writing is performed.

The gate voltage switching unit 105 includes a resistance control switch 115. The resistance control switch 115 switches the voltages Vg0, Vg1, and Vg2 on the basis of a switching signal Tg1. At this time, the switching signal Tg1 can cause the resistance control switch 115 to select the voltage Vg0 at the time of latch operation. The switching signal Tg1 can cause the resistance control switch 115 to select the voltage Vg1 at the time of low resistance writing and select the voltage Vg2 at the time of high resistance writing. At this time, the switching signal Tg1 switches the gate voltage Vg in the order of Vg1, Vg2 at the time of storing. The resistance control switch 115 may include a MOS transistor.

Here, in a case where each of the voltage-controlled magneto-resistive effect elements 114 and 124 is in the high resistance state in the case where low resistance writing is performed, the reversal voltage is applied to each of the voltage-controlled magneto-resistive effect elements 114 and 124 on the basis of the gate voltage Vg1. In a case where each of the voltage-controlled magneto-resistive effect elements 114 and 124 is in the low resistance state in the case where low resistance writing is performed, a voltage smaller than the reversal voltage is applied to each of the voltage-controlled magneto-resistive effect elements 114 and 124 on the basis of the gate voltage Vg1. The voltage smaller than the reversal voltage may be 0 V. In a case where each of the voltage-controlled magneto-resistive effect elements 114 and 124 is in the low-resistance state in the case where high resistance writing is performed, the reversal voltage is applied to each of the voltage-controlled magneto-resistive effect elements 114 and 124 on the basis of the gate voltage Vg2. In a case where each of the voltage-controlled magneto-resistive effect elements 114 and 124 is in the high resistance state in the case where high resistance writing is performed, a voltage larger than the reversal voltage is applied to each of the voltage-controlled magneto-resistive effect elements 114 and 124 on the basis of the gate voltage Vg2.

The voltage driver 106 drives each of the voltage-controlled magneto-resistive effect elements 114 and 124 so that the reversal voltage can be applied to each of the voltage-controlled magneto-resistive effect elements 114 and 124. Here, the voltage driver 106 can apply a drive voltage Vx to the free layer 143 of each of the voltage-controlled magneto-resistive effect elements 114 and 124 via the drive terminal ND. At this time, the voltage driver 106 can switch the drive voltage Vx between drive voltages Vx1 and Vx2 at the time of storing. Here, the voltage driver 106 selects the drive voltage Vx1 at the time of storing, and then switches to the drive voltage Vx2.

The drive voltage Vx1 is set so that the reversal voltage is applied to one of the voltage-controlled magneto-resistive effect elements 114 and 124 and the perpendicular magnetic anisotropy of the other of the voltage-controlled magneto-resistive effect elements 114 and 124 increases. The drive voltage Vx2 is set so that the reversal voltage is applied to the other of the voltage-controlled magneto-resistive effect elements 114 and 124, and the voltage smaller than the reversal voltage is applied to the one of the voltage-controlled magneto-resistive effect elements 114 and 124. Then, the voltage driver 106 applies the drive voltage Vx1 to each of the voltage-controlled magneto-resistive effect elements 114 and 124 according to node voltages VA and VB corresponding to the data held in each of the volatile storage nodes N and NB, and then applies the drive voltage Vx2.

When the reversal voltage is applied to the one of the voltage-controlled magneto-resistive effect elements 114 and 124 on the basis of the application of the drive voltage Vx1, a voltage higher than the reversal voltage by a difference between the node voltages VA and VB may be applied to the other of the voltage-controlled magneto-resistive effect elements 114 and 124. When the reversal voltage is applied to the other of the voltage-controlled magneto-resistive effect elements 114 and 124 on the basis of the application of the drive voltage Vx2, a voltage lower than the reversal voltage by a difference between the node voltages VA and VB may be applied to the one of the voltage-controlled magneto-resistive effect elements 114 and 124.

The voltage driver 106 includes a voltage selector switch 116. The voltage selector switch 116 switches the drive voltages Vx1 and Vx2 on the basis of a switching signal Tx1. At this time, the switching signal Tx1 can cause the voltage selector switch 116 to select the drive voltage Vx1 in low resistance writing and select the drive voltage Vx2 in high resistance writing. Furthermore, the switching signal Tx1 can cause the voltage selector switch 116 to select the drive voltage Vx2 at the time of restoring. The voltage selector switch 116 may include a MOS transistor.

Here, in a case where data is complementarily stored from the latch circuit 102 to the voltage-controlled magneto-resistive effect elements 114 and 124, a voltage having the same polarity applied to the voltage-controlled magneto-resistive effect elements 114 and 124 is changed stepwise. On the basis of the stepwise change of the voltage, first storing operation and subsequent second storing operation are performed.

In the first storing operation, when the gate voltage Vg1 is applied to each of the MOS transistors 113 and 123, the drive voltage Vx1 is applied to the free layers 143 of the voltage-controlled magneto-resistive effect elements 114 and 124. At this time, the reversal voltage is applied to one of the voltage-controlled magneto-resistive effect elements 114 and 124, low resistance writing is performed for the one of the voltage-controlled magneto-resistive effect elements 114 and 124, and the perpendicular magnetic anisotropy of the other of the voltage-controlled magneto-resistive effect elements 114 and 124 increases. When the perpendicular magnetic anisotropy of the other of the voltage-controlled magneto-resistive effect elements 114 and 124 increases, the magnetization direction of the other of the voltage-controlled magneto-resistive effect elements 114 and 124 may be reversed. Even in a case where the magnetization direction of the other of the voltage-controlled magneto-resistive effect elements 114 and 124 is reversed in the first storing operation, the magnetization direction of the other of the voltage-controlled magneto-resistive effect elements 114 and 124 can be correctly set in the subsequent second storing operation.

In the second storing operation, when the gate voltage Vg2 is applied to each of the MOS transistors 113 and 123, the drive voltage Vx2 is applied to the free layers 143 of the voltage-controlled magneto-resistive effect elements 114 and 124. At this time, the reversal voltage is applied to the other of the voltage-controlled magneto-resistive effect elements 114 and 124, high resistance writing is performed for the one of the voltage-controlled magneto-resistive effect elements 114 and 124, and the voltage smaller than the reversal voltage is applied to the one of the voltage-controlled magneto-resistive effect elements 114 and 124. Here, since the voltage smaller than the reversal voltage is applied to the one of the voltage-controlled magneto-resistive effect elements 114 and 124, the low resistance state of the one of the voltage-controlled magneto-resistive effect elements 114 and 124 is maintained.

For example, in a case where a logical value ‘0’ is held in the volatile storage node N and a logical value ‘1’ is held in the volatile storage node NB, the voltage-controlled magneto-resistive effect element 114 is set to the low resistance state, and the voltage-controlled magneto-resistive effect element 124 is set to the high resistance state. On the other hand, in a case where the logical value ‘1’ is held in the volatile storage node N and the logical value ‘0’ is held in the volatile storage node NB, the voltage-controlled magneto-resistive effect element 114 is set to the high resistance state, and the voltage-controlled magneto-resistive effect element 124 is set to the low resistance state. Such a relationship between the logical values of the volatile storage nodes N and NB and the resistance states of the voltage-controlled magneto-resistive effect elements 114 and 124 is referred to as the forward logic.

Furthermore, in a case where the data is complementarily restored from the voltage-controlled magneto-resistive effect elements 114 and 124 to the latch circuit 102, a voltage lower than a voltage applied to the pinned layer 141 is applied to the free layer 143. At this time, the original data is written back to the latch circuit 102 according to the resistance state of each of the voltage-controlled magneto-resistive effect elements 114 and 124, and the resistance state of each of the voltage-controlled magneto-resistive effect elements 114 and 124 is maintained.

Hereinafter, the latch operation, storing operation, and restoring operation of the storage device 100 will be described. Note that, in the following description, in order to simplify the description, as an example, a case will be taken where the logical value ‘0’ is held in the volatile storage node N and the logical value ‘1’ is held in the volatile storage node NB, and, at that time, the node voltage VA is 0 V and the node voltage VB is 1 V. Furthermore, as an example, a case will be taken where the drive voltage Vx1 is set to −1 V and the drive voltage Vx2 is set to 0 V. Note that the node voltages VA and VB and the drive voltages Vx1 and Vx2 are not limited to these values.

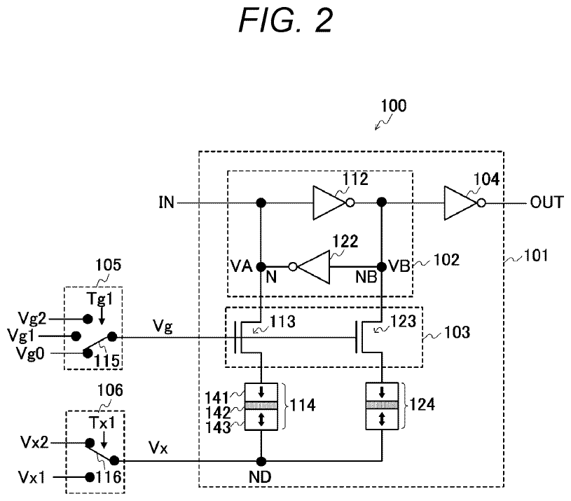

FIG. 2 is a diagram illustrating an example of the latch operation of the storage device according to the first embodiment.

In the figure, in the latch operation, the gate voltage Vg is set to Vg0=0 V. For this reason, the MOS transistors 113 and 123 are turned off, and the latch circuit 102 is disconnected from the voltage-controlled magneto-resistive effect elements 114 and 124.

At this time, in a case where the logical value of the input data IN is ‘0’, the logical value ‘0’ is held in the volatile storage node N, and the logical value ‘1’ is held in the volatile storage node NB. In a case where the logical value of the input data IN is ‘1’, the logical value ‘1’ is held in the volatile storage node N, and the logical value ‘0’ is held in the volatile storage node NB.

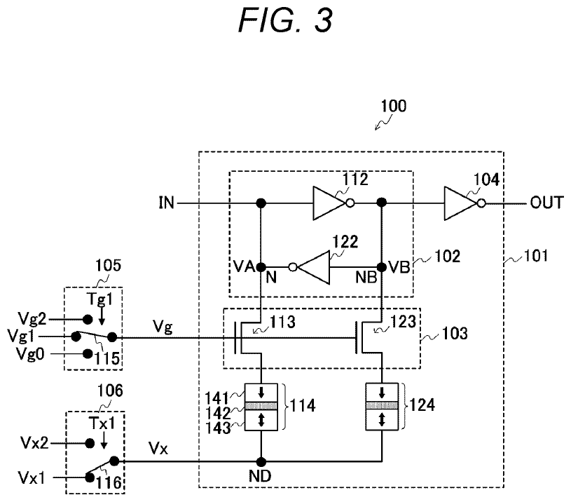

FIG. 3 is a diagram illustrating an example of the first storing operation of the storage device according to the first embodiment.

In the figure, in the first storing operation, the gate voltage Vg is set to Vg1, and the drive voltage Vx is set to Vx1=−1 V. For this reason, a voltage of 1 V is applied between the volatile storage node N and the drive terminal ND, and a voltage of 2 V is applied between the volatile storage node NB and the drive terminal ND. At this time, the voltage between the volatile storage node N and the drive terminal ND is divided into a voltage applied to the on-resistance of the MOS transistor 113 and a cell voltage applied to the voltage-controlled magneto-resistive effect element 114. Then, the gate voltage Vg1 is set so that when the voltage between the volatile storage node N and the drive terminal ND is divided by the on-resistance of the MOS transistor 113, the cell voltage applied to the voltage-controlled magneto-resistive effect element 114 in the high resistance state matches the reversal voltage.

Here, in a case where the voltage-controlled magneto-resistive effect element 114 is in the high resistance state at the time of low resistance writing, since the reversal voltage is applied to the voltage-controlled magneto-resistive effect element 114, the voltage-controlled magneto-resistive effect element 114 transitions from the high resistance state to the low resistance state. On the other hand, in a case where the voltage-controlled magneto-resistive effect element 114 is in the low resistance state at the time of low resistance writing, a voltage division ratio to the on-resistance of the MOS transistor 113 increases as compared with the case where the voltage-controlled magneto-resistive effect element 114 is in the high resistance state. For this reason, the cell voltage applied to the voltage-controlled magneto-resistive effect element 114 is smaller than the reversal voltage, and the low resistance state of the voltage-controlled magneto-resistive effect element 114 is maintained due to the perpendicular magnetic anisotropy of the voltage-controlled magneto-resistive effect element 114.

On the other hand, the voltage of 2 V is applied between the volatile storage node NB and the drive terminal ND, and the cell voltage of the voltage-controlled magneto-resistive effect element 124 is larger than the cell voltage of the voltage-controlled magneto-resistive effect element 114. However, for the voltage-controlled magneto-resistive effect element 124, writing is performed in the second storing operation, and thus the resistance state of the voltage-controlled magneto-resistive effect element 124 may be any state.

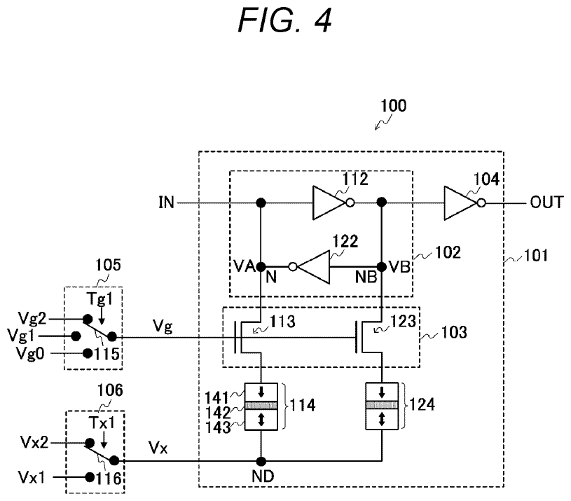

FIG. 4 is a diagram illustrating an example of the second storing operation and the restoring operation of the storage device according to the first embodiment.

In the figure, in the second storing operation, the gate voltage Vg is set to Vg2, and the drive voltage Vx is set to Vx2=0 V. For this reason, a voltage of 0 V is applied between the volatile storage node N and the drive terminal ND, and the voltage of 1 V is applied between the volatile storage node NB and the drive terminal ND. At this time, the voltage between the volatile storage node NB and the drive terminal ND is divided into a voltage applied to the on-resistance of the MOS transistor 123 and a cell voltage applied to the voltage-controlled magneto-resistive effect element 124. Then, the gate voltage Vg2 is set so that when the voltage between the volatile storage node NB and the drive terminal ND is divided by the on-resistance of the MOS transistor 123, the cell voltage applied to the voltage-controlled magneto-resistive effect element 124 in the low resistance state matches the reversal voltage.

Here, in a case where the voltage-controlled magneto-resistive effect element 124 is in the low resistance state at the time of high resistance writing, since the reversal voltage is applied to the voltage-controlled magneto-resistive effect element 124, the voltage-controlled magneto-resistive effect element 124 transitions from the low resistance state to the high resistance state. On the other hand, in a case where the voltage-controlled magneto-resistive effect element 124 is in the high resistance state at the time of high resistance writing, the voltage division ratio to the on-resistance of the MOS transistor 123 decreases as compared with the case where the voltage-controlled magneto-resistive effect element 124 is in the low resistance state. For this reason, the cell voltage applied to the voltage-controlled magneto-resistive effect element 124 is larger than the reversal voltage, and an in-plane rotational component appears due to in-plane magnetic anisotropy of the voltage-controlled magneto-resistive effect element 124, but the rotational component does not contribute to reversal of the magnetization direction, so that the high resistance state of the voltage-controlled magneto-resistive effect element 124 is maintained.

Note that, in the case where the voltage-controlled magneto-resistive effect element 124 is in the low resistance state, the voltage division ratio of the voltage-controlled magneto-resistive effect element 124 decreases as compared with the case of the high resistance state. For this reason, in order to make the reversal voltages substantially equal to each other, the reversal voltages being a reversal voltage when the voltage-controlled magneto-resistive effect element 124 is in the low resistance state and a reversal voltage when the voltage-controlled magneto-resistive effect element 124 is in the high resistance state, in a case where the voltage-controlled magneto-resistive effect element 124 is in the low resistance state, the on-resistance of the MOS transistor 123 is reduced as compared with the case of the high resistance state. In order to reduce the on-resistance of the MOS transistor 123, the gate voltage Vg2 is increased as compared with the gate voltage Vg1.

On the other hand, the voltage of 0 V is applied between the volatile storage node N and the drive terminal ND, and the cell voltage of the voltage-controlled magneto-resistive effect element 114 is 0 V. For this reason, the magnetization direction of the voltage-controlled magneto-resistive effect element 114 does not change, and the low resistance state of the voltage-controlled magneto-resistive effect element 114 is maintained.

In the figure, in the restoring operation, the gate voltage Vg is set to Vg2, and the drive voltage Vx is set to Vx2=0 V. Here, it is assumed that the voltage-controlled magneto-resistive effect element 114 is in the low resistance state and the voltage-controlled magneto-resistive effect element 124 is in the high resistance state. At this time, the node voltage VA is lower than the node voltage VB, and the logical value ‘0’ is restored in the volatile storage node N and the logical value ‘1’ is restored in the volatile storage node NB.

Here, when the logical value ‘0’ is restored in the volatile storage node N, the node voltage VA is 0 V, and no voltage is applied to the voltage-controlled magneto-resistive effect element 114, so that the low resistance state of the voltage-controlled magneto-resistive effect element 114 is maintained. On the other hand, when the logical value ‘1’ is restored in the volatile storage node NB, the node voltage VB is 1 V, and the voltage of 1 V is applied to the voltage-controlled magneto-resistive effect element 124. At this time, the gate voltage Vg is set to Vg2, and when the voltage-controlled magneto-resistive effect element 124 is in the high resistance state, the high resistance state of the voltage-controlled magneto-resistive effect element 124 is maintained as it is.

Note that, in the description of the first storing operation, the second storing operation, and the restoring operation of the first embodiment, as an example, the case has been taken where the logical value ‘0’ is held in the volatile storage node N and the logical value ‘1’ is held in the volatile storage node NB. The first storing operation, the second storing operation, and the restoring operation of the first embodiment are similar also in the case where the logical value ‘1’ is held in the volatile storage node N and the logical value ‘0’ is held in the volatile storage node NB.

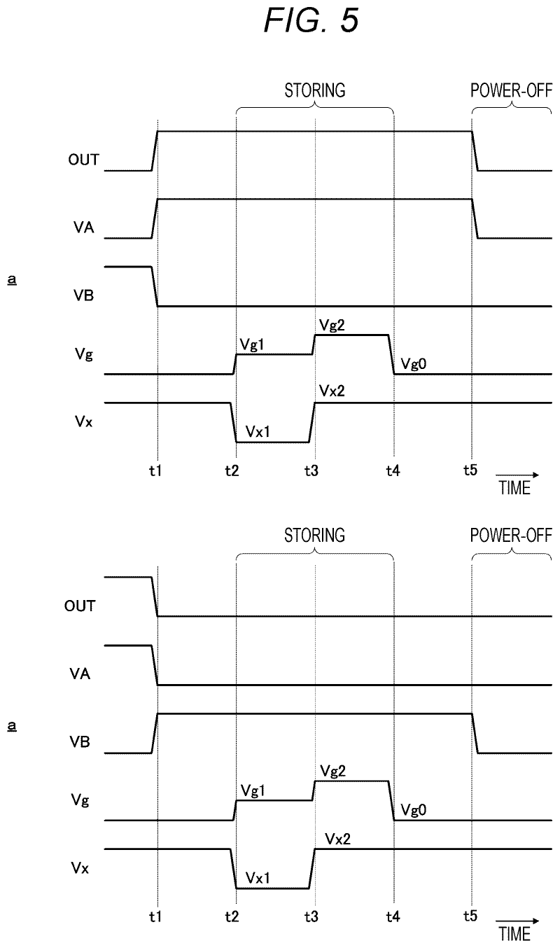

FIG. 5 is a timing chart illustrating an example of a storing timing of the storage device according to the first embodiment. Note that, in a of the figure, a voltage waveform is illustrated of each unit at the time of storing in the case where the logical value ‘1’ is held in the volatile storage node N and the logical value ‘0’ is held in the volatile storage node NB. In b of the figure, a voltage waveform is illustrated of each unit at the time of storing in a case where the logical value ‘0’ is held in the volatile storage node N and the logical value ‘1’ is held in the volatile storage node NB.

In a of the figure, it is assumed that the logical value ‘1’ is held in the volatile storage node N, and the logical value ‘0’ is held in the volatile storage node NB. At this time, the node voltage VA is set to 1 V, the node voltage VB is set to 0 V, and the output data OUT is set to the logical value ‘1’ (t1).

Next, the voltage Vg1 is selected as the gate voltage Vg, and the voltage Vx1=−1 V is selected as the drive voltage Vx (t2). At this time, the first storing operation is performed, and the voltage-controlled magneto-resistive effect element 124 is set to the low resistance state.

Next, the voltage Vg2 is selected as the gate voltage Vg, and the voltage Vx2=0 V is selected as the drive voltage Vx (t3). At this time, the second storing operation is performed, and the voltage-controlled magneto-resistive effect element 114 is set to the high resistance state.

Next, the voltage Vg0 is selected as the gate voltage Vg (t4). At this time, the voltage-controlled magneto-resistive effect elements 114 and 124 are disconnected from the latch circuit 102.

Next, the storage device 100 is powered off (t5). At this time, the data held in the latch circuit 102 is lost. On the other hand, the voltage-controlled magneto-resistive effect element 114 maintains the high resistance state, and the voltage-controlled magneto-resistive effect element 124 maintains the low resistance state.

In b of the figure, it is assumed that the logical value ‘0’ is held in the volatile storage node N, and the logical value ‘1’ is held in the volatile storage node NB. At this time, the node voltage VA is set to 0 V, the node voltage VB is set to 1 V, and the output data OUT is set to the logical value ‘0’ (t1).

Next, the voltage Vg1 is selected as the gate voltage Vg, and the voltage Vx1=−1 V is selected as the drive voltage Vx (t2). At this time, the first storing operation is performed, and the voltage-controlled magneto-resistive effect element 114 is set to the low resistance state.

Next, the voltage Vg2 is selected as the gate voltage Vg, and the voltage Vx2=0 V is selected as the drive voltage Vx (t3). At this time, the second storing operation is performed, and the voltage-controlled magneto-resistive effect element 124 is set to the high resistance state.

Next, the voltage Vg0 is selected as the gate voltage Vg (t4). At this time, the voltage-controlled magneto-resistive effect elements 114 and 124 are disconnected from the latch circuit 102.

Next, the storage device 100 is powered off (t5). At this time, the data held in the latch circuit 102 is lost. On the other hand, the voltage-controlled magneto-resistive effect element 114 maintains the low resistance state, and the voltage-controlled magneto-resistive effect element 124 maintains the high resistance state.

As described above, in the storing operation of the storage device 100, regardless of whether the output data OUT from the latch circuit 102 is the logical value ‘0’ or the logical value ‘1’, low resistance writing is performed in the first storing operation, and high resistance writing is performed in the second storing operation.

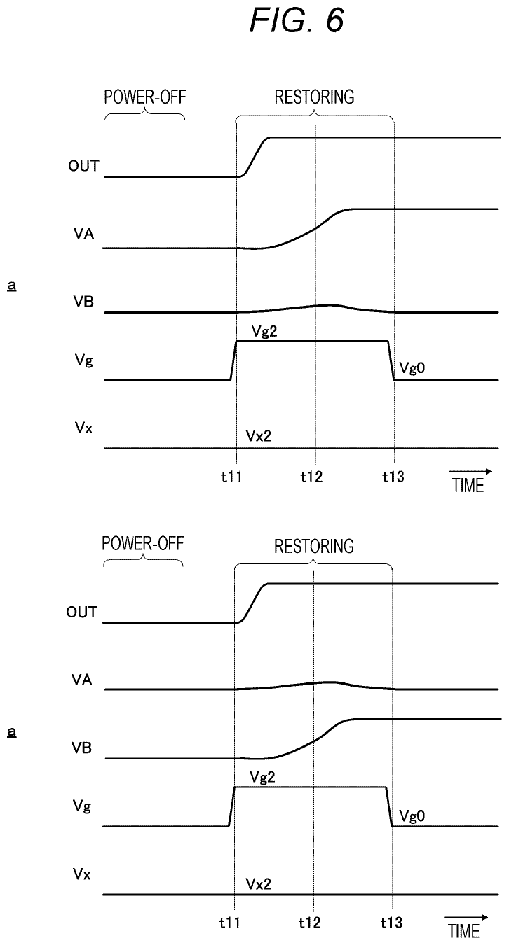

FIG. 6 is a timing chart illustrating an example of a restoring timing of the storage device according to the first embodiment. Note that, in a of the figure, a voltage waveform is illustrated of each unit when the logical value ‘1’ is restored in the volatile storage node N and the logical value ‘0’ is restored in the volatile storage node NB. In b of the figure, a voltage waveform is illustrated of each unit at the time of restoring the logical value ‘0’ in the volatile storage node N and the logical value ‘1’ in the volatile storage node NB.

In a of the figure, it is assumed that charge of the latch circuit 102 is discharged by power-off of the storage device 100 after the storing to the voltage-controlled magneto-resistive effect elements 114 and 124. At this time, it is assumed that the voltage-controlled magneto-resistive effect element 114 holds the high resistance state, and the voltage-controlled magneto-resistive effect element 124 holds the low resistance state.

Here, at the time of restoring, the voltage Vg2 is selected as the gate voltage Vg, and the voltage Vx2=0 V is selected as the drive voltage Vx (t11). At this time, the node voltage VA is higher than the node voltage VB (t12), and the logical value ‘1’ is restored in the volatile storage node N and the logical value ‘0’ is restored in the volatile storage node NB.

Next, the voltage Vg0 is selected as the gate voltage Vg (t13). At this time, the voltage-controlled magneto-resistive effect elements 114 and 124 are disconnected from the latch circuit 102. Furthermore, the voltage-controlled magneto-resistive effect element 114 maintains the high resistance state, and the voltage-controlled magneto-resistive effect element 124 maintains the low resistance state.

In b of the figure, it is assumed that the voltage-controlled magneto-resistive effect element 114 holds the low resistance state, and the voltage-controlled magneto-resistive effect element 124 holds the low resistance state.

Here, at the time of restoring, the voltage Vg2 is selected as the gate voltage Vg, and the voltage Vx2=0 V is selected as the drive voltage Vx (t11). At this time, the node voltage VA is lower than the node voltage VB (t12), and the logical value ‘0’ is restored in the volatile storage node N and the logical value ‘1’ is restored in the volatile storage node NB.

Next, the voltage Vg0 is selected as the gate voltage Vg (t13). At this time, the voltage-controlled magneto-resistive effect elements 114 and 124 are disconnected from the latch circuit 102. Furthermore, the voltage-controlled magneto-resistive effect element 114 maintains the low resistance state, and the voltage-controlled magneto-resistive effect element 124 maintains the high resistance state.

As described above, in the first embodiment, the voltage-controlled magneto-resistive effect elements 114 and 124 are provided in the latch circuit 102. As a result, the data held in the latch circuit 102 can be stored in the voltage-controlled magneto-resistive effect elements 114 and 124 on the basis of voltage drive. For this reason, it is possible to add a nonvolatile storage function to the latch circuit 102 while suppressing an increase in power consumption when the data held in the latch circuit 102 is stored in the voltage-controlled magneto-resistive effect elements 114 and 124.

Furthermore, the MOS transistors 113 and 123 that can vary resistances between the latch circuit 102 and the respective voltage-controlled magneto-resistive effect elements 114 and 124 are connected between the latch circuit 102 and the respective voltage-controlled magneto-resistive effect elements 114 and 124. As a result, each of the voltage-controlled magneto-resistive effect elements 114 and 124 can transition from the high resistance state to the low resistance state while maintaining the low resistance state at the time of low resistance writing, and can transition from the low resistance state to the high resistance state while maintaining the high resistance state at the time of high resistance writing.

At this time, each of the MOS transistors 113 and 123 can change the resistance to cause the cell voltages to be substantially equal to each other, the cell voltages being a cell voltage when each of the voltage-controlled magneto-resistive effect elements 114 and 124 transitions from the high resistance state to the low resistance state and a cell voltage when each of the voltage-controlled magneto-resistive effect elements 114 and 124 transitions from the low resistance state to the high resistance state. As a result, data can be written to each of the voltage-controlled magneto-resistive effect elements 114 and 124 on the basis of the cell voltages having the same polarity applied to the respective voltage-controlled magneto-resistive effect elements 114 and 124.

Furthermore, in a case where data is stored from the latch circuit 102 to each of the voltage-controlled magneto-resistive effect elements 114 and 124, when the gate voltage Vg1 is applied to each of the MOS transistors 113 and 123, the drive voltage Vx1 is applied to the free layer 143 of each of the voltage-controlled magneto-resistive effect elements 114 and 124. Thereafter, when the gate voltage Vg2 is applied to each of the MOS transistors 113 and 123, the drive voltage Vx2 is applied to the free layer 143 of each of the voltage-controlled magneto-resistive effect elements 114 and 124.

As a result, without destroying the low resistance state at the time of low resistance writing for one of the voltage-controlled magneto-resistive effect elements 114 and 124, after the low resistance writing, it is possible to perform high resistance writing for the other of the voltage-controlled magneto-resistive effect elements 114 and 124. For this reason, the logical value ‘0’ of the latch circuit 102 can be held as the low resistance state in one of the voltage-controlled magneto-resistive effect elements 114 and 124, and the logical value ‘1’ of the latch circuit 102 can be held as the high resistance state in the other of the voltage-controlled magneto-resistive effect elements 114 and 124.

Furthermore, in a case where the data is restored from each of the voltage-controlled magneto-resistive effect elements 114 and 124 to the latch circuit 102, the voltage lower than the voltage applied to the pinned layer 141 of each of the voltage-controlled magneto-resistive effect elements 114 and 124 is applied to the free layer 143. As a result, it is possible to restore the data from each of the voltage-controlled magneto-resistive effect elements 114 and 124 to the latch circuit 102 without destroying the data held in each of the voltage-controlled magneto-resistive effect elements 114 and 124.

### 2. Second Embodiment

In the first embodiment, the voltage-controlled magneto-resistive effect elements 114 and 124 are provided in the latch circuit 102, the drive voltage Vx is applied to the free layer 143 of each of the voltage-controlled magneto-resistive effect elements 114 and 124, and the forward logic of the latch circuit 102 is stored. In this second embodiment, the voltage-controlled magneto-resistive effect elements 114 and 124 are provided in the latch circuit 102, the drive voltage Vx is applied to the free layers 143 of the voltage-controlled magneto-resistive effect elements 114 and 124, and the inverse logic of the latch circuit 102 is stored.

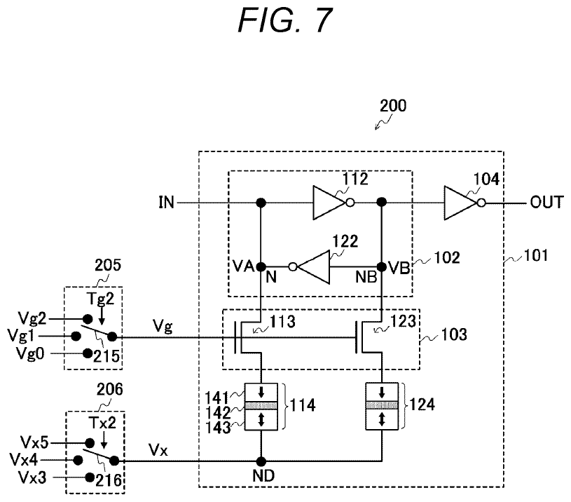

FIG. 7 is a diagram illustrating a configuration example of a storage device according to the second embodiment.

In the figure, a storage device 200 includes a gate voltage switching unit 205 and a voltage driver 206 instead of the gate voltage switching unit 105 and the voltage driver 106 of the first embodiment. The configuration of the storage device 200 of the second embodiment other than that is similar to the configuration of the storage device 100 of the first embodiment.

The gate voltage switching unit 205 switches the gate voltage Vg among the voltages Vg0, Vg1, and Vg2. At this time, the gate voltage switching unit 205 switches the gate voltage Vg so that high resistance writing is performed and then low resistance writing is performed at the time of storing.

The gate voltage switching unit 205 includes a resistance control switch 215. The resistance control switch 215 switches the voltages Vg0, Vg1, and Vg2 on the basis of a switching signal Tg2. At this time, the switching signal Tg2 can cause the resistance control switch 215 to select the voltage Vg0 at the time of latch operation. The switching signal Tg2 can cause the resistance control switch 215 to select the voltage Vg1 at the time of low resistance writing and select the voltage Vg2 at the time of high resistance writing. At this time, the switching signal Tg2 switches the gate voltage Vg in the order of Vg2, Vg1 at the time of storing.

The voltage driver 206 drives each of the voltage-controlled magneto-resistive effect elements 114 and 124 so that the reversal voltage can be applied to each of the voltage-controlled magneto-resistive effect elements 114 and 124. Here, the voltage driver 206 can apply the drive voltage Vx to the free layer 143 of each of the voltage-controlled magneto-resistive effect elements 114 and 124 via the drive terminal ND. At this time, the voltage driver 206 can switch the drive voltage Vx between drive voltages Vx4 and Vx5 at the time of storing. Furthermore, the voltage driver 206 can switch the drive voltage Vx to a drive voltage V3 at the time of restoring.

The drive voltage Vx4 is set so that the reversal voltage is applied to one of the voltage-controlled magneto-resistive effect elements 114 and 124 and the perpendicular magnetic anisotropy of the other of the voltage-controlled magneto-resistive effect elements 114 and 124 increases. The drive voltage Vx5 is set so that the reversal voltage is applied to the other of the voltage-controlled magneto-resistive effect elements 114 and 124, and the voltage smaller than the reversal voltage is applied to the one of the voltage-controlled magneto-resistive effect elements 114 and 124. A drive voltage Vx3 is set so that a voltage higher than the voltage applied to the pinned layer 141 at the time of restoring is applied to the free layer 143.

Then, the voltage driver 206 applies the drive voltage Vx4 to each of the voltage-controlled magneto-resistive effect elements 114 and 124 according to the node voltages VA and VB corresponding to the data held in each of the volatile storage nodes N and NB, and then applies the drive voltage Vx5. Furthermore, the voltage driver 206 applies the drive voltage Vx3 at the time of restoring.

The voltage driver 206 includes a voltage selector switch 216. The voltage selector switch 216 switches the drive voltages Vx3, Vx4, and Vx5 on the basis of a switching signal Tx2. At this time, the switching signal Tx2 can cause the voltage selector switch 216 to select the drive voltage Vx4 in high resistance writing and select the drive voltage Vx5 in low resistance writing. Furthermore, the switching signal Tx2 can cause the voltage selector switch 216 to select the drive voltage Vx3 at the time of restoring.

Here, in the first embodiment, low resistance writing is performed in the first storing operation, and then high resistance writing is performed in the second storing operation. In the second embodiment, high resistance writing is performed in the first storing operation, and then low resistance writing is performed in the second storing operation. At this time, in the second embodiment, the inverse logic of the latch circuit 102 is stored in the voltage-controlled magneto-resistive effect elements 114 and 124.

For example, in the case where the logical value ‘0’ is held in the volatile storage node N and the logical value ‘1’ is held in the volatile storage node NB, the voltage-controlled magneto-resistive effect element 114 is set to the high resistance state, and the voltage-controlled magneto-resistive effect element 124 is set to the low resistance state. On the other hand, in a case where the logical value ‘1’ is held in the volatile storage node N and the logical value ‘0’ is held in the volatile storage node NB, the voltage-controlled magneto-resistive effect element 114 is set to the low resistance state, and the voltage-controlled magneto-resistive effect element 124 is set to the high resistance state. Such a relationship between the logical values of the volatile storage nodes N and NB and the resistance states of the voltage-controlled magneto-resistive effect elements 114 and 124 is referred to as the inverse logic.

Furthermore, in the case where the data is complementarily restored from the voltage-controlled magneto-resistive effect elements 114 and 124 to the latch circuit 102, the drive voltage Vx3 is applied to the free layer 143. Note that the gate voltage Vg may be any voltage as long as each of the MOS transistors 113 and 123 is turned on. At this time, the original data is written back to the latch circuit 102 according to the resistance state of each of the voltage-controlled magneto-resistive effect elements 114 and 124. Furthermore, at the time of restoring, the voltage higher than the voltage applied to the pinned layer 141 is applied to the free layer 143. For this reason, a voltage is applied to each of the voltage-controlled magneto-resistive effect elements 114 and 124 so that the perpendicular magnetic anisotropy thereof increases, and the resistance state of each of the voltage-controlled magneto-resistive effect elements 114 and 124 is maintained.

Hereinafter, the latch operation, storing operation, and restoring operation of the storage device 200 will be described. Note that, in the following description, in order to simplify the description, as an example, a case will be taken where the logical value ‘0’ is held in the volatile storage node N and the logical value ‘1’ is held in the volatile storage node NB, and, at that time, the node voltage VA is 0 V and the node voltage VB is 1 V. Furthermore, as an example, a case will be taken where the drive voltage Vx3 is set to 1 V, the drive voltage Vx4 is set to 0 V, and the drive voltage Vx5 is set to −1 V. Note that the node voltages VA and VB and the drive voltages Vx3, Vx4, and Vx5 are not limited to these values.

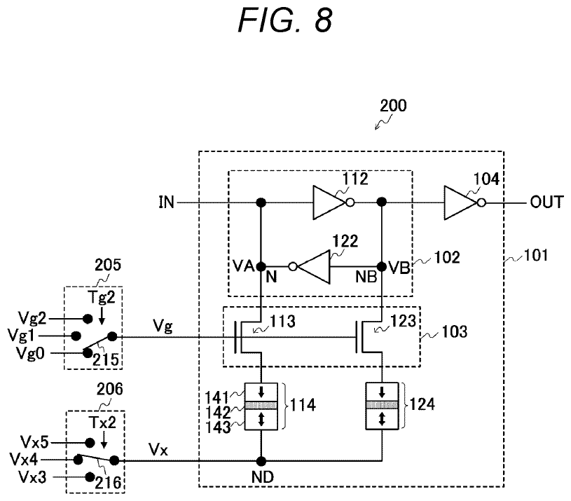

FIG. 8 is a diagram illustrating an example of the latch operation of the storage device according to the second embodiment.

In the figure, in the latch operation, the gate voltage Vg is set to Vg0=0 V. For this reason, the MOS transistors 113 and 123 are turned off, and the latch circuit 102 is disconnected from the voltage-controlled magneto-resistive effect elements 114 and 124.

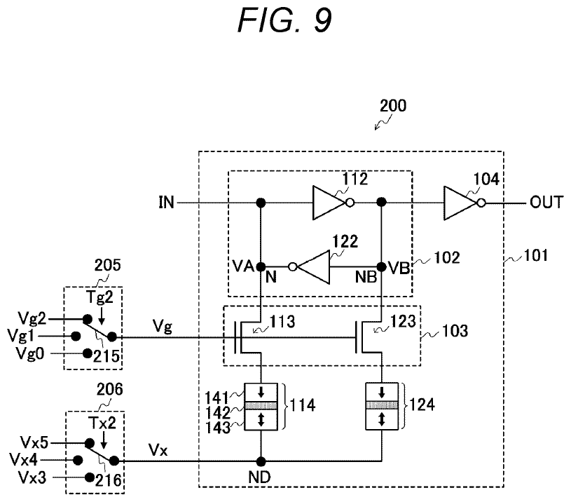

FIG. 9 is a diagram illustrating an example of the first storing operation of the storage device according to the second embodiment.

In the figure, in the first storing operation, the gate voltage Vg is set to Vg2, and the drive voltage Vx is set to Vx5=−1 V. For this reason, the voltage of 1 V is applied between the volatile storage node N and the drive terminal ND, and the voltage of 2 V is applied between the volatile storage node NB and the drive terminal ND. At this time, the voltage between the volatile storage node N and the drive terminal ND is divided into a voltage applied to the on-resistance of the MOS transistor 113 and a cell voltage applied to the voltage-controlled magneto-resistive effect element 114. Then, the gate voltage Vg2 is set so that when the voltage between the volatile storage node N and the drive terminal ND is divided by the on-resistance of the MOS transistor 113, the cell voltage applied to the voltage-controlled magneto-resistive effect element 114 in the low resistance state matches the reversal voltage.

Here, in a case where the voltage-controlled magneto-resistive effect element 114 is in the low resistance state at the time of high resistance writing, since the reversal voltage is applied to the voltage-controlled magneto-resistive effect element 114, the voltage-controlled magneto-resistive effect element 114 transitions from the low resistance state to the high resistance state. On the other hand, in a case where the voltage-controlled magneto-resistive effect element 114 is in the high resistance state at the time of high resistance writing, the voltage division ratio to the on-resistance of the MOS transistor 113 decreases as compared with the case where the voltage-controlled magneto-resistive effect element 114 is in the low resistance state. For this reason, the cell voltage applied to the voltage-controlled magneto-resistive effect element 114 is larger than the reversal voltage, and the high resistance state of the voltage-controlled magneto-resistive effect element 114 is maintained due to the perpendicular magnetic anisotropy of the voltage-controlled magneto-resistive effect element 114.

On the other hand, the voltage of 2 V is applied between the volatile storage node NB and the drive terminal ND, and the cell voltage of the voltage-controlled magneto-resistive effect element 124 is larger than the cell voltage of the voltage-controlled magneto-resistive effect element 114. However, for the voltage-controlled magneto-resistive effect element 124, writing is performed in the second storing operation, and thus the resistance state of the voltage-controlled magneto-resistive effect element 124 may be any state.

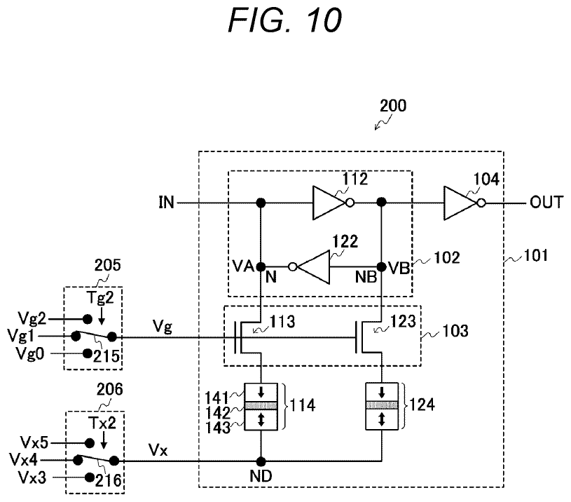

FIG. 10 is a diagram illustrating an example of the second storing operation of the storage device according to the second embodiment.

In the figure, in the second storing operation, the gate voltage Vg is set to Vg1, and the drive voltage Vx is set to Vx4=0 V. For this reason, the voltage of 0 V is applied between the volatile storage node N and the drive terminal ND, and the voltage of 1 V is applied between the volatile storage node NB and the drive terminal ND. At this time, the voltage between the volatile storage node NB and the drive terminal ND is divided into a voltage applied to the on-resistance of the MOS transistor 123 and a cell voltage applied to the voltage-controlled magneto-resistive effect element 124. The gate voltage Vg1 is set so that when the voltage between the volatile storage node NB and the drive terminal ND is divided by the on-resistance of the MOS transistor 123, the cell voltage applied to the voltage-controlled magneto-resistive effect element 124 in the high resistance state matches the reversal voltage.

Here, in a case where the voltage-controlled magneto-resistive effect element 124 is in the high resistance state at the time of low resistance writing, since the reversal voltage is applied to the voltage-controlled magneto-resistive effect element 124, the voltage-controlled magneto-resistive effect element 124 transitions from the high resistance state to the low resistance state. On the other hand, in a case where the voltage-controlled magneto-resistive effect element 124 is in the low resistance state at the time of low resistance writing, the voltage division ratio to the on-resistance of the MOS transistor 123 increases as compared with the case where the voltage-controlled magneto-resistive effect element 124 is in the high resistance state. For this reason, the cell voltage applied to the voltage-controlled magneto-resistive effect element 124 is smaller than the reversal voltage, and an in-plane rotational component appears due to the in-plane magnetic anisotropy of the voltage-controlled magneto-resistive effect element 124, but the rotational component does not contribute to reversal of the magnetization direction, so that the low resistance state of the voltage-controlled magneto-resistive effect element 124 is maintained.

On the other hand, the voltage of 0 V is applied between the volatile storage node N and the drive terminal ND, and the cell voltage of the voltage-controlled magneto-resistive effect element 114 is 0 V. For this reason, the magnetization direction of the voltage-controlled magneto-resistive effect element 114 does not change, and the high resistance state of the voltage-controlled magneto-resistive effect element 114 is maintained.

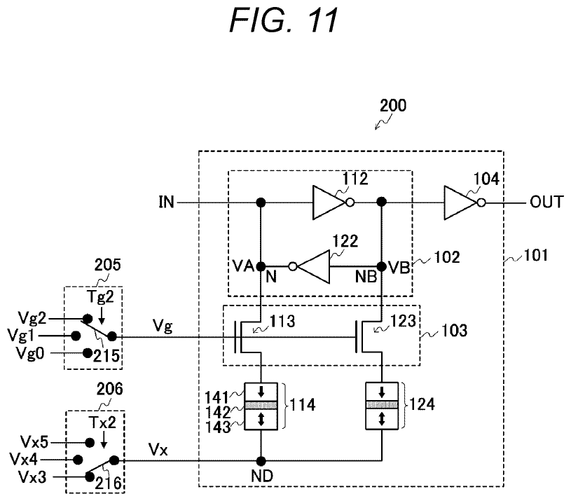

FIG. 11 is a diagram illustrating an example of the restoring operation of the storage device according to the second embodiment.

In the figure, in the restoring operation, the gate voltage Vg is set to Vg2, and the drive voltage Vx is set to Vx3=1 V. In the restoring operation, the gate voltage Vg is not limited to Vg2, and any voltage may be used as long as each of the MOS transistors 113 and 123 is turned on. Here, it is assumed that the voltage-controlled magneto-resistive effect element 114 is in the high resistance state and the voltage-controlled magneto-resistive effect element 124 is in the low resistance state. At this time, the node voltage VA is lower than the node voltage VB, and the logical value ‘0’ is restored in the volatile storage node N and the logical value ‘1’ is restored in the volatile storage node NB.

Here, when the logical value ‘0’ is restored in the volatile storage node N, the node voltage VA is 0 V, and the voltage of 1 V is applied to the voltage-controlled magneto-resistive effect element 114. However, the direction in which the voltage of 1 V is applied to the voltage-controlled magneto-resistive effect element 114 is a direction in which the voltage of the free layer 143 is higher than the voltage of the pinned layer 141. In this case, the perpendicular magnetic anisotropy of the voltage-controlled magneto-resistive effect element 114 increases, and the high resistance state of the voltage-controlled magneto-resistive effect element 114 is maintained as it is. On the other hand, when the logical value ‘1’ is restored in the volatile storage node NB, the node voltage VB is 1 V, and no voltage is applied to the voltage-controlled magneto-resistive effect element 124, so that the low resistance state of the voltage-controlled magneto-resistive effect element 124 is maintained.

Note that, in the description of the first storing operation, the second storing operation, and the restoring operation of the second embodiment, as an example, the case has been taken where the logical value ‘0’ is held in the volatile storage node N and the logical value ‘1’ is held in the volatile storage node NB. The first storing operation, the second storing operation, and the restoring operation of the second embodiment are similar also in the case where the logical value ‘1’ is held in the volatile storage node N and the logical value ‘0’ is held in the volatile storage node NB.

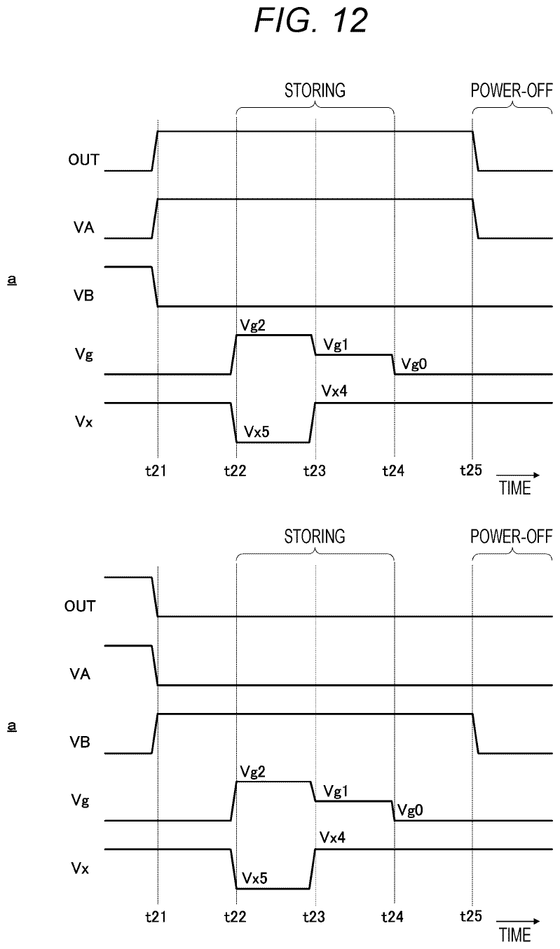

FIG. 12 is a timing chart illustrating an example of the storing timing of the storage device according to the second embodiment. Note that, in a of the figure, a voltage waveform is illustrated of each unit at the time of storing in the case where the logical value ‘1’ is held in the volatile storage node N and the logical value ‘0’ is held in the volatile storage node NB. In b of the figure, a voltage waveform is illustrated of each unit at the time of storing in a case where the logical value ‘0’ is held in the volatile storage node N and the logical value ‘1’ is held in the volatile storage node NB.

In a of the figure, it is assumed that the logical value ‘1’ is held in the volatile storage node N, and the logical value ‘0’ is held in the volatile storage node NB. At this time, the node voltage VA is set to 1 V, the node voltage VB is set to 0 V, and the output data OUT is set to the logical value ‘1’ (t21).

Next, the voltage Vg2 is selected as the gate voltage Vg, and the voltage Vx5=−1 V is selected as the drive voltage Vx (t22). At this time, the first storing operation is performed, and the voltage-controlled magneto-resistive effect element 124 is set to the high resistance state.

Next, the voltage Vg1 is selected as the gate voltage Vg, and the voltage Vx4=0 V is selected as the drive voltage Vx (t23). At this time, the second storing operation is performed, and the voltage-controlled magneto-resistive effect element 114 is set to the low resistance state.

Next, the voltage Vg0 is selected as the gate voltage Vg (t24). At this time, the voltage-controlled magneto-resistive effect elements 114 and 124 are disconnected from the latch circuit 102.

Next, the storage device 100 is powered off (t25). At this time, the data held in the latch circuit 102 is lost. On the other hand, the voltage-controlled magneto-resistive effect element 114 maintains the low resistance state, and the voltage-controlled magneto-resistive effect element 124 maintains the high resistance state.

In b of the figure, it is assumed that the logical value ‘0’ is held in the volatile storage node N, and the logical value ‘1’ is held in the volatile storage node NB. At this time, the node voltage VA is set to 0 V, the node voltage VB is set to 1 V, and the output data OUT is set to the logical value ‘0’ (t21).

Next, the voltage Vg2 is selected as the gate voltage Vg, and the voltage Vx5=−1 V is selected as the drive voltage Vx (t22). At this time, the first storing operation is performed, and the voltage-controlled magneto-resistive effect element 114 is set to the high resistance state.

Next, the voltage Vg1 is selected as the gate voltage Vg, and the voltage Vx4=0 V is selected as the drive voltage Vx (t23). At this time, the second storing operation is performed, and the voltage-controlled magneto-resistive effect element 124 is set to the low resistance state.

Next, the voltage Vg0 is selected as the gate voltage Vg (t24). At this time, the voltage-controlled magneto-resistive effect elements 114 and 124 are disconnected from the latch circuit 102.

Next, the storage device 100 is powered off (t25). At this time, the data held in the latch circuit 102 is lost. On the other hand, the voltage-controlled magneto-resistive effect element 114 maintains the high resistance state, and the voltage-controlled magneto-resistive effect element 124 maintains the low resistance state.

As described above, in the storing operation of the storage device 200, regardless of whether the output data OUT from the latch circuit 102 is the logical value ‘0’ or the logical value ‘1’, high resistance writing is performed in the first storing operation, and low resistance writing is performed in the second storing operation.

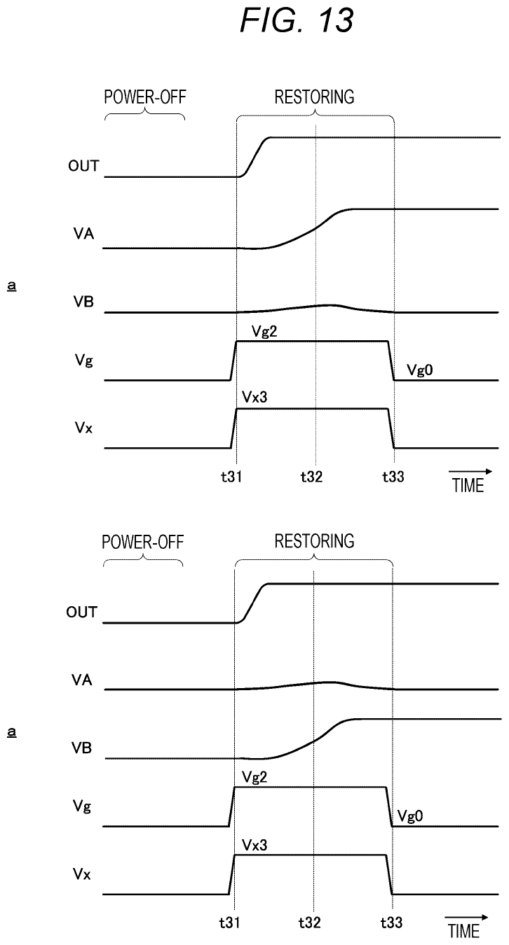

FIG. 13 is a timing chart illustrating an example of the restoring timing of the storage device according to the second embodiment. Note that, in a of the figure, a voltage waveform is illustrated of each unit when the logical value ‘1’ is restored in the volatile storage node N and the logical value ‘0’ is restored in the volatile storage node NB. In b of the figure, a voltage waveform is illustrated of each unit at the time of restoring the logical value ‘0’ in the volatile storage node N and the logical value ‘1’ in the volatile storage node NB.

In a of the figure, it is assumed that charge of the latch circuit 102 is discharged by power-off of the storage device 200 after the storing to the voltage-controlled magneto-resistive effect elements 114 and 124. At this time, it is assumed that the voltage-controlled magneto-resistive effect element 114 holds the low resistance state, and the voltage-controlled magneto-resistive effect element 124 holds the high resistance state.

Here, at the time of restoring, the voltage Vg2 is selected as the gate voltage Vg, and the voltage Vx3=1 V is selected as the drive voltage Vx (t31). At this time, the node voltage VA is higher than the node voltage VB (t32), and the logical value ‘1’ is restored in the volatile storage node N and the logical value ‘0’ is restored in the volatile storage node NB.

Next, the voltage Vg0 is selected as the gate voltage Vg (t33). At this time, the voltage-controlled magneto-resistive effect elements 114 and 124 are disconnected from the latch circuit 102. Furthermore, the voltage-controlled magneto-resistive effect element 114 maintains the low resistance state, and the voltage-controlled magneto-resistive effect element 124 maintains the high resistance state.

In b of the figure, it is assumed that the voltage-controlled magneto-resistive effect element 114 holds the high resistance state, and the voltage-controlled magneto-resistive effect element 124 holds the low resistance state.

Here, at the time of restoring, the voltage Vg2 is selected as the gate voltage Vg, and the voltage Vx3=1 V is selected as the drive voltage Vx (t31). At this time, the node voltage VA is lower than the node voltage VB (t32), and the logical value ‘0’ is restored in the volatile storage node N and the logical value ‘1’ is restored in the volatile storage node NB.

Next, the voltage Vg0 is selected as the gate voltage Vg (t33). At this time, the voltage-controlled magneto-resistive effect elements 114 and 124 are disconnected from the latch circuit 102. Furthermore, the voltage-controlled magneto-resistive effect element 114 maintains the high resistance state, and the voltage-controlled magneto-resistive effect element 124 maintains the low resistance state.

As described above, in the second embodiment, in a case where data is stored from the latch circuit 102 to each of the voltage-controlled magneto-resistive effect elements 114 and 124, when the gate voltage Vg2 is applied to each of the MOS transistors 113 and 123, the drive voltage Vx5 is applied to the free layer 143 of each of the voltage-controlled magneto-resistive effect elements 114 and 124. Thereafter, when the gate voltage Vg1 is applied to each of the MOS transistors 113 and 123, the drive voltage Vx4 is applied to the free layer 143 of each of the voltage-controlled magneto-resistive effect elements 114 and 124.

As a result, without destroying the high resistance state at the time of high resistance writing for one of the voltage-controlled magneto-resistive effect elements 114 and 124, after the high resistance writing, it is possible to perform low resistance writing for the other of the voltage-controlled magneto-resistive effect elements 114 and 124. For this reason, the logical value ‘0’ of the latch circuit 102 can be held as the high resistance state in one of the voltage-controlled magneto-resistive effect elements 114 and 124, and the logical value ‘1’ of the latch circuit 102 can be held as the low resistance state in the other of the voltage-controlled magneto-resistive effect elements 114 and 124.

Furthermore, in a case where the data is restored from each of the voltage-controlled magneto-resistive effect elements 114 and 124 to the latch circuit 102, the voltage higher than the voltage applied to the pinned layer 141 of each of the voltage-controlled magneto-resistive effect elements 114 and 124 is applied to the free layer 143. As a result, the voltage can be applied so that the perpendicular magnetic anisotropy of each of the voltage-controlled magneto-resistive effect elements 114 and 124 increases at the time of restoring. For this reason, it is possible to restore the data from each of the voltage-controlled magneto-resistive effect elements 114 and 124 to the latch circuit 102 without destroying the data held in each of the voltage-controlled magneto-resistive effect elements 114 and 124.

### 3. Third Embodiment

In the first embodiment, the voltage-controlled magneto-resistive effect elements 114 and 124 are provided in the latch circuit 102, the drive voltage Vx is applied to the free layer 143 of each of the voltage-controlled magneto-resistive effect elements 114 and 124, and the forward logic of the latch circuit 102 is stored. In this third embodiment, the voltage-controlled magneto-resistive effect elements 114 and 124 are provided in the latch circuit 102, the drive voltage Vx is applied to the pinned layers 141 of the voltage-controlled magneto-resistive effect elements 114 and 124, and the forward logic of the latch circuit 102 is stored.

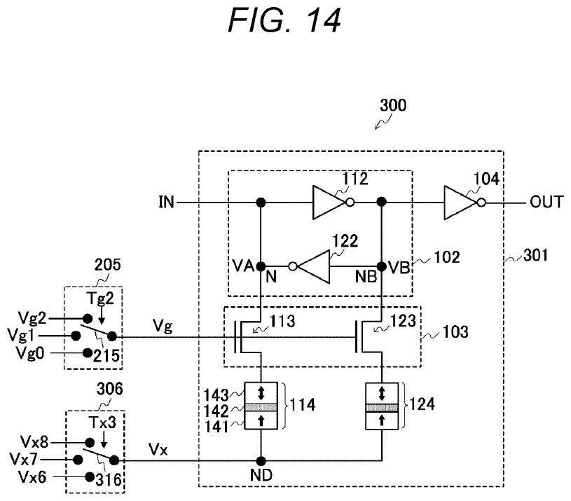

FIG. 14 is a diagram illustrating a configuration example of a storage device according to the third embodiment.

In the figure, a storage device 300 includes a latch cell 301 and a voltage driver 306 instead of the latch cell 101 and the voltage driver 206 of the second embodiment. The configuration of the storage device 300 of the third embodiment other than that is similar to the configuration of the storage device 200 of the second embodiment.

In the latch cell 101 of the second embodiment, the free layer 143 of each of the voltage-controlled magneto-resistive effect elements 114 and 124 is connected to the drive terminal ND. In the latch cell 301 of the third embodiment, the pinned layer 141 of each of the voltage-controlled magneto-resistive effect elements 114 and 124 is connected to the drive terminal ND. The configuration of the latch cell 301 of the third embodiment other than that is similar to the configuration of the latch cell 101 of the second embodiment.

The voltage driver 306 drives each of the voltage-controlled magneto-resistive effect elements 114 and 124 so that the reversal voltage can be applied to each of the voltage-controlled magneto-resistive effect elements 114 and 124. Here, the voltage driver 306 can apply the drive voltage Vx to the pinned layer 141 of each of the voltage-controlled magneto-resistive effect elements 114 and 124 via the drive terminal ND. At this time, the voltage driver 306 can switch the drive voltage Vx between the drive voltages Vx7 and Vx8 at the time of storing. Furthermore, the voltage driver 306 can switch the drive voltage Vx to the drive voltage V6 at the time of restoring.

The drive voltage Vx8 is set so that the reversal voltage is applied to one of the voltage-controlled magneto-resistive effect elements 114 and 124 and the perpendicular magnetic anisotropy of the other of the voltage-controlled magneto-resistive effect elements 114 and 124 increases. The drive voltage Vx7 is set so that the reversal voltage is applied to the other of the voltage-controlled magneto-resistive effect elements 114 and 124, and the voltage smaller than the reversal voltage is applied to the one of the voltage-controlled magneto-resistive effect elements 114 and 124. The drive voltage Vx6 is set so that a voltage lower than the voltage applied to the free layer 143 at the time of restoring is applied to the pinned layer 141. The drive voltage Vx6 may be set to a ground potential.

Then, the voltage driver 306 applies the drive voltage Vx8 to each of the voltage-controlled magneto-resistive effect elements 114 and 124 according to the node voltages VA and VB corresponding to the data held in each of the volatile storage nodes N and NB, and then applies the drive voltage Vx7. Furthermore, the voltage driver 306 applies the drive voltage Vx6 at the time of restoring.

The voltage driver 306 includes a voltage selector switch 316. The voltage selector switch 316 switches the drive voltages Vx6, Vx7, and Vx8 on the basis of a switching signal Tx3. At this time, the switching signal Tx3 can cause the voltage selector switch 316 to select the drive voltage Vx8 in high resistance writing and select the drive voltage Vx7 in low resistance writing. Furthermore, the switching signal Tx3 can cause the voltage selector switch 316 to select the drive voltage Vx6 at the time of restoring.

Here, in the third embodiment, as in the second embodiment, high resistance writing is performed in the first storing operation, and then low resistance writing is performed in the second storing operation. At this time, in the third embodiment, as in the first embodiment, the forward logic of the latch circuit 102 is stored in the voltage-controlled magneto-resistive effect elements 114 and 124.

Furthermore, in the case where the data is complementarily restored from the voltage-controlled magneto-resistive effect elements 114 and 124 to the latch circuit 102, the drive voltage Vx6 is applied to the pinned layer 141. At this time, the original data is written back to the latch circuit 102 according to the resistance state of each of the voltage-controlled magneto-resistive effect elements 114 and 124. Furthermore, at the time of restoring, the voltage lower than the voltage applied to the free layer 143 is applied to the pinned layer 141. For this reason, a voltage is applied to each of the voltage-controlled magneto-resistive effect elements 114 and 124 so that the perpendicular magnetic anisotropy thereof increases, and the resistance state of each of the voltage-controlled magneto-resistive effect elements 114 and 124 is maintained.

Hereinafter, the latch operation, storing operation, and restoring operation of the storage device 300 will be described. Note that, in the following description, in order to simplify the description, as an example, a case will be taken where the logical value ‘0’ is held in the volatile storage node N and the logical value ‘1’ is held in the volatile storage node NB, and, at that time, the node voltage VA is 0 V and the node voltage VB is 1 V. Furthermore, as an example, a case will be taken where the drive voltage Vx6 is set to 0 V, the drive voltage Vx7 is set to 1 V, and the drive voltage Vx8 is set to 2 V. Note that the node voltages VA and VB and the drive voltages Vx6, Vx7, and Vx8 are not limited to these values.

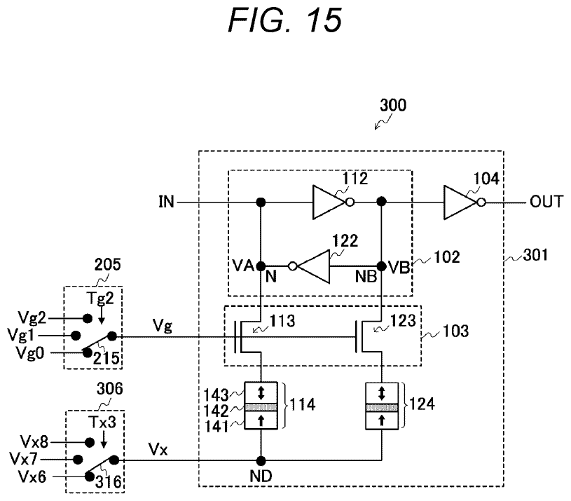

FIG. 15 is a diagram illustrating an example of the latch operation of the storage device according to the third embodiment.

In the figure, in the latch operation, the gate voltage Vg is set to Vg0=0 V. For this reason, the MOS transistors 113 and 123 are turned off, and the latch circuit 102 is disconnected from the voltage-controlled magneto-resistive effect elements 114 and 124.

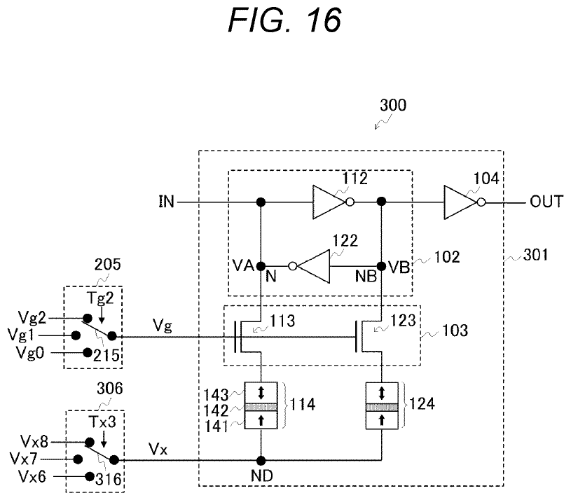

FIG. 16 is a diagram illustrating an example of the first storing operation of the storage device according to the third embodiment.

In the figure, in the first storing operation, the gate voltage Vg is set to Vg2, and the drive voltage Vx is set to Vx8=2 V. For this reason, the voltage of 2 V is applied between the volatile storage node N and the drive terminal ND, and the voltage of 1 V is applied between the volatile storage node NB and the drive terminal ND. At this time, the voltage between the volatile storage node NB and the drive terminal ND is divided into a voltage applied to the on-resistance of the MOS transistor 123 and a cell voltage applied to the voltage-controlled magneto-resistive effect element 124. Then, the gate voltage Vg2 is set so that when the voltage between the volatile storage node NB and the drive terminal ND is divided by the on-resistance of the MOS transistor 123, the cell voltage applied to the voltage-controlled magneto-resistive effect element 124 in the low resistance state matches the reversal voltage.

Here, in a case where the voltage-controlled magneto-resistive effect element 124 is in the low resistance state at the time of high resistance writing, since the reversal voltage is applied to the voltage-controlled magneto-resistive effect element 124, the voltage-controlled magneto-resistive effect element 124 transitions from the low resistance state to the high resistance state. On the other hand, in a case where the voltage-controlled magneto-resistive effect element 124 is in the high resistance state at the time of high resistance writing, the voltage division ratio to the on-resistance of the MOS transistor 123 decreases as compared with the case where the voltage-controlled magneto-resistive effect element 124 is in the low resistance state. For this reason, the cell voltage applied to the voltage-controlled magneto-resistive effect element 124 is larger than the reversal voltage, and the high resistance state of the voltage-controlled magneto-resistive effect element 124 is maintained due to the perpendicular magnetic anisotropy of the voltage-controlled magneto-resistive effect element 124.

On the other hand, the voltage of 2 V is applied between the volatile storage node N and the drive terminal ND, and the cell voltage of the voltage-controlled magneto-resistive effect element 114 is larger than the cell voltage of the voltage-controlled magneto-resistive effect element 124. However, for the voltage-controlled magneto-resistive effect element 114, writing is performed in the second storing operation, and thus the resistance state of the voltage-controlled magneto-resistive effect element 114 may be any state.

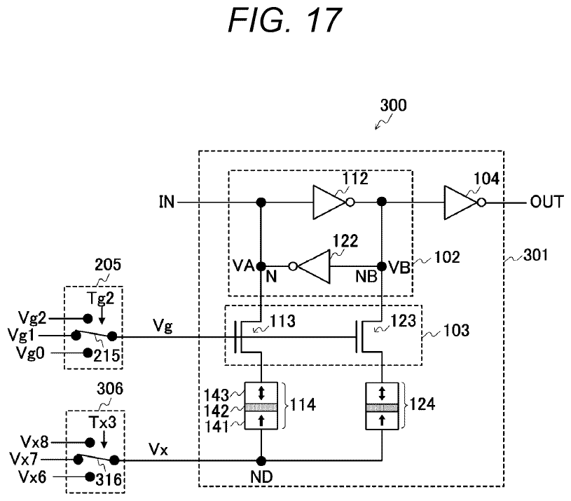

FIG. 17 is a diagram illustrating an example of the second storing operation of the storage device according to the third embodiment.

In the figure, in the second storing operation, the gate voltage Vg is set to Vg1, and the drive voltage Vx is set to Vx7=1 V. For this reason, the voltage of 1 V is applied between the volatile storage node N and the drive terminal ND, and the voltage of 0 V is applied between the volatile storage node NB and the drive terminal ND. At this time, the voltage between the volatile storage node N and the drive terminal ND is divided into a voltage applied to the on-resistance of the MOS transistor 113 and a cell voltage applied to the voltage-controlled magneto-resistive effect element 114. Then, the gate voltage Vg1 is set so that when the voltage between the volatile storage node N and the drive terminal ND is divided by the on-resistance of the MOS transistor 113, the cell voltage applied to the voltage-controlled magneto-resistive effect element 114 in the high resistance state matches the reversal voltage.

Here, in a case where the voltage-controlled magneto-resistive effect element 114 is in the high resistance state at the time of low resistance writing, since the reversal voltage is applied to the voltage-controlled magneto-resistive effect element 114, the voltage-controlled magneto-resistive effect element 114 transitions from the high resistance state to the low resistance state. On the other hand, in a case where the voltage-controlled magneto-resistive effect element 114 is in the low resistance state at the time of low resistance writing, a voltage division ratio to the on-resistance of the MOS transistor 113 increases as compared with the case where the voltage-controlled magneto-resistive effect element 114 is in the high resistance state. For this reason, the cell voltage applied to the voltage-controlled magneto-resistive effect element 114 is smaller than the reversal voltage, and an in-plane rotational component appears due to the in-plane magnetic anisotropy of the voltage-controlled magneto-resistive effect element 114, but the rotational component does not contribute to reversal of the magnetization direction, so that the low resistance state of the voltage-controlled magneto-resistive effect element 114 is maintained.

On the other hand, the voltage of 0 V is applied between the volatile storage node NB and the drive terminal ND, and the cell voltage of the voltage-controlled magneto-resistive effect element 124 is 0 V. For this reason, the magnetization direction of the voltage-controlled magneto-resistive effect element 124 does not change, and the high resistance state of the voltage-controlled magneto-resistive effect element 124 is maintained.

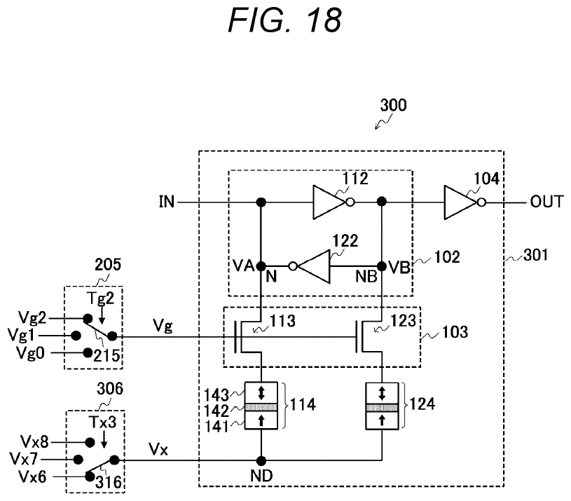

FIG. 18 is a diagram illustrating an example of the restoring operation of the storage device according to the third embodiment.

In the figure, in the restoring operation, the gate voltage Vg is set to Vg2, and the drive voltage Vx is set to Vx6=0 V. Here, it is assumed that the voltage-controlled magneto-resistive effect element 114 is in the high resistance state and the voltage-controlled magneto-resistive effect element 124 is in the low resistance state. At this time, the node voltage VA is lower than the node voltage VB, and the logical value ‘0’ is restored in the volatile storage node N and the logical value ‘1’ is restored in the volatile storage node NB.

Here, when the logical value ‘1’ is restored in the volatile storage node NB, the node voltage VB is 1 V, and the voltage of 1 V is applied to the voltage-controlled magneto-resistive effect element 124. However, the direction in which the voltage of 1 V is applied to the voltage-controlled magneto-resistive effect element 124 is a direction in which the voltage of the free layer 143 is higher than the voltage of the pinned layer 141. In this case, the perpendicular magnetic anisotropy of the voltage-controlled magneto-resistive effect element 124 increases, and the high resistance state of the voltage-controlled magneto-resistive effect element 124 is maintained as it is. On the other hand, when the logical value ‘0’ is restored in the volatile storage node N, the node voltage VA is 0 V, and no voltage is applied to the voltage-controlled magneto-resistive effect element 114, so that the low resistance state of the voltage-controlled magneto-resistive effect element 114 is maintained.

Note that, in the description of the first storing operation, the second storing operation, and the restoring operation of the third embodiment, as an example, the case has been taken where the logical value ‘0’ is held in the volatile storage node N and the logical value ‘1’ is held in the volatile storage node NB. The first storing operation, the second storing operation, and the restoring operation of the third embodiment are similar also in the case where the logical value ‘1’ is held in the volatile storage node N and the logical value ‘0’ is held in the volatile storage node NB.

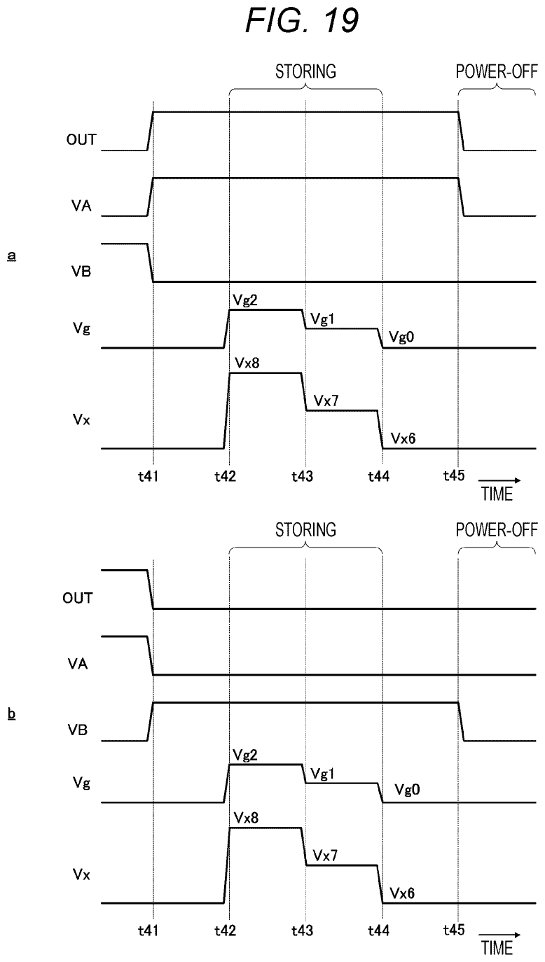

FIG. 19 is a timing chart illustrating an example of the storing timing of the storage device according to the third embodiment. Note that, in a of the figure, a voltage waveform is illustrated of each unit at the time of storing in the case where the logical value ‘1’ is held in the volatile storage node N and the logical value ‘0’ is held in the volatile storage node NB. In b of the figure, a voltage waveform is illustrated of each unit at the time of storing in a case where the logical value ‘0’ is held in the volatile storage node N and the logical value ‘1’ is held in the volatile storage node NB.

In a of the figure, it is assumed that the logical value ‘1’ is held in the volatile storage node N, and the logical value ‘0’ is held in the volatile storage node NB. At this time, the node voltage VA is set to 1 V, the node voltage VB is set to 0 V, and the output data OUT is set to the logical value ‘1’ (t41).

Next, the voltage Vg2 is selected as the gate voltage Vg, and the voltage Vx8=2 V is selected as the drive voltage Vx (t42). At this time, the first storing operation is performed, and the voltage-controlled magneto-resistive effect element 114 is set to the high resistance state.

Next, the voltage Vg1 is selected as the gate voltage Vg, and the voltage Vx7=1 V is selected as the drive voltage Vx (t43). At this time, the second storing operation is performed, and the voltage-controlled magneto-resistive effect element 124 is set to the low resistance state.

Next, the voltage Vg0 is selected as the gate voltage Vg (t44). At this time, the voltage-controlled magneto-resistive effect elements 114 and 124 are disconnected from the latch circuit 102.

Next, the storage device 100 is powered off (t45). At this time, the data held in the latch circuit 102 is lost. On the other hand, the voltage-controlled magneto-resistive effect element 114 maintains the high resistance state, and the voltage-controlled magneto-resistive effect element 124 maintains the low resistance state.

In b of the figure, it is assumed that the logical value ‘0’ is held in the volatile storage node N, and the logical value ‘1’ is held in the volatile storage node NB. At this time, the node voltage VA is set to 0 V, the node voltage VB is set to 1 V, and the output data OUT is set to the logical value ‘0’ (t41).

Next, the voltage Vg2 is selected as the gate voltage Vg, and the voltage Vx8=2 V is selected as the drive voltage Vx (t42). At this time, the first storing operation is performed, and the voltage-controlled magneto-resistive effect element 124 is set to the high resistance state.

Next, the voltage Vg1 is selected as the gate voltage Vg, and the voltage Vx7=1 V is selected as the drive voltage Vx (t43). At this time, the second storing operation is performed, and the voltage-controlled magneto-resistive effect element 114 is set to the low resistance state.

Next, the voltage Vg0 is selected as the gate voltage Vg (t44). At this time, the voltage-controlled magneto-resistive effect elements 114 and 124 are disconnected from the latch circuit 102.

Next, the storage device 100 is powered off (t45). At this time, the data held in the latch circuit 102 is lost. On the other hand, the voltage-controlled magneto-resistive effect element 114 maintains the low resistance state, and the voltage-controlled magneto-resistive effect element 124 maintains the high resistance state.

As described above, in the storing operation of the storage device 300, regardless of whether the output data OUT from the latch circuit 102 is the logical value ‘0’ or the logical value ‘1’, high resistance writing is performed in the first storing operation, and low resistance writing is performed in the second storing operation.

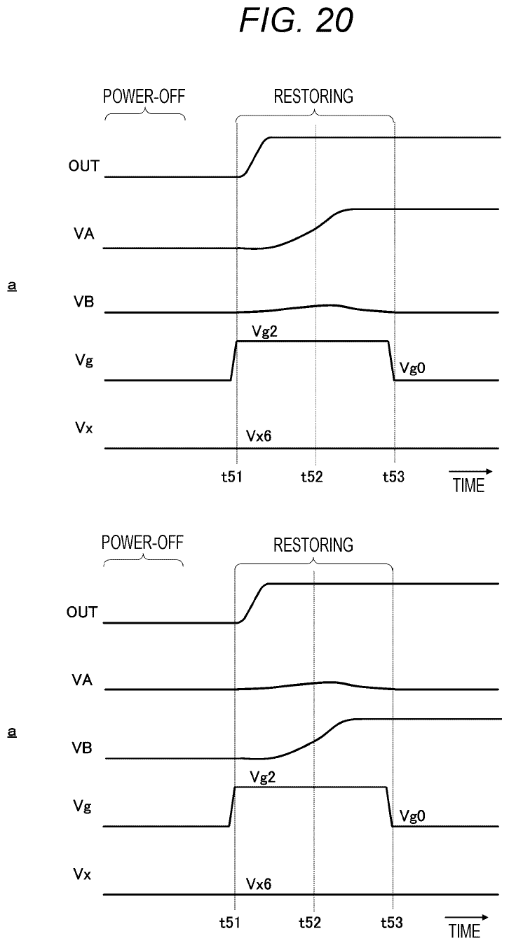

FIG. 20 is a timing chart illustrating an example of the restoring timing of the storage device according to the third embodiment. Note that, in a of the figure, a voltage waveform is illustrated of each unit when the logical value ‘1’ is restored in the volatile storage node N and the logical value ‘0’ is restored in the volatile storage node NB. In b of the figure, a voltage waveform is illustrated of each unit at the time of restoring the logical value ‘0’ in the volatile storage node N and the logical value ‘1’ in the volatile storage node NB.

In a of the figure, it is assumed that charge of the latch circuit 102 is discharged by power-off of the storage device 300 after the storing to the voltage-controlled magneto-resistive effect elements 114 and 124. At this time, it is assumed that the voltage-controlled magneto-resistive effect element 114 holds the high resistance state, and the voltage-controlled magneto-resistive effect element 124 holds the low resistance state.

Here, at the time of restoring, the voltage Vg2 is selected as the gate voltage Vg, and the voltage Vx6=0 V is selected as the drive voltage Vx (t51). At this time, the node voltage VA is higher than the node voltage VB (t52), and the logical value ‘1’ is restored in the volatile storage node N and the logical value ‘0’ is restored in the volatile storage node NB.

Next, the voltage Vg0 is selected as the gate voltage Vg (t53). At this time, the voltage-controlled magneto-resistive effect elements 114 and 124 are disconnected from the latch circuit 102. Furthermore, the voltage-controlled magneto-resistive effect element 114 maintains the high resistance state, and the voltage-controlled magneto-resistive effect element 124 maintains the low resistance state.

In b of the figure, it is assumed that the voltage-controlled magneto-resistive effect element 114 holds the low resistance state, and the voltage-controlled magneto-resistive effect element 124 holds the high resistance state.

Here, at the time of restoring, the voltage Vg2 is selected as the gate voltage Vg, and the voltage Vx6=0 V is selected as the drive voltage Vx (t51). At this time, the node voltage VA is lower than the node voltage VB (t52), and the logical value ‘0’ is restored in the volatile storage node N and the logical value ‘1’ is restored in the volatile storage node NB.

Next, the voltage Vg0 is selected as the gate voltage Vg (t53). At this time, the voltage-controlled magneto-resistive effect elements 114 and 124 are disconnected from the latch circuit 102. Furthermore, the voltage-controlled magneto-resistive effect element 114 maintains the low resistance state, and the voltage-controlled magneto-resistive effect element 124 maintains the high resistance state.

As described above, in the third embodiment, in a case where data is stored from the latch circuit 102 to each of the voltage-controlled magneto-resistive effect elements 114 and 124, when the gate voltage Vg2 is applied to each of the MOS transistors 113 and 123, the drive voltage Vx8 is applied to the pinned layer 141 of each of the voltage-controlled magneto-resistive effect elements 114 and 124. Thereafter, when the gate voltage Vg1 is applied to each of the MOS transistors 113 and 123, the drive voltage Vx7 is applied to the pinned layer 141 of each of the voltage-controlled magneto-resistive effect elements 114 and 124.

As a result, without destroying the high resistance state at the time of high resistance writing for one of the voltage-controlled magneto-resistive effect elements 114 and 124, after the high resistance writing, it is possible to perform low resistance writing for the other of the voltage-controlled magneto-resistive effect elements 114 and 124. For this reason, the logical value ‘0’ of the latch circuit 102 can be held as the low resistance state in one of the voltage-controlled magneto-resistive effect elements 114 and 124, and the logical value ‘1’ of the latch circuit 102 can be held as the high resistance state in the other of the voltage-controlled magneto-resistive effect elements 114 and 124. At this time, in order to store data from the latch circuit 102 to each of the voltage-controlled magneto-resistive effect elements 114 and 124, it is only required to set the drive voltages Vx7 and Vx8 to positive voltages, and it is possible to make a negative voltage unnecessary.

Furthermore, in a case where the data is restored from each of the voltage-controlled magneto-resistive effect elements 114 and 124 to the latch circuit 102, the voltage lower than the voltage applied to the free layer 143 of each of the voltage-controlled magneto-resistive effect elements 114 and 124 is applied to the pinned layer 141. As a result, the voltage can be applied so that the perpendicular magnetic anisotropy of each of the voltage-controlled magneto-resistive effect elements 114 and 124 increases at the time of restoring. For this reason, it is possible to restore the data from each of the voltage-controlled magneto-resistive effect elements 114 and 124 to the latch circuit 102 without destroying the data held in each of the voltage-controlled magneto-resistive effect elements 114 and 124.

### 4. Fourth Embodiment

In the third embodiment, the voltage-controlled magneto-resistive effect elements 114 and 124 are provided in the latch circuit 102, the drive voltage Vx is applied to the pinned layer 141 of each of the voltage-controlled magneto-resistive effect elements 114 and 124, and the forward logic of the latch circuit 102 is stored. In this fourth embodiment, the voltage-controlled magneto-resistive effect elements 114 and 124 are provided in the latch circuit 102, the drive voltage Vx is applied to the pinned layer 141 of the voltage-controlled magneto-resistive effect elements 114 and 124, and the inverse logic of the latch circuit 102 is stored.

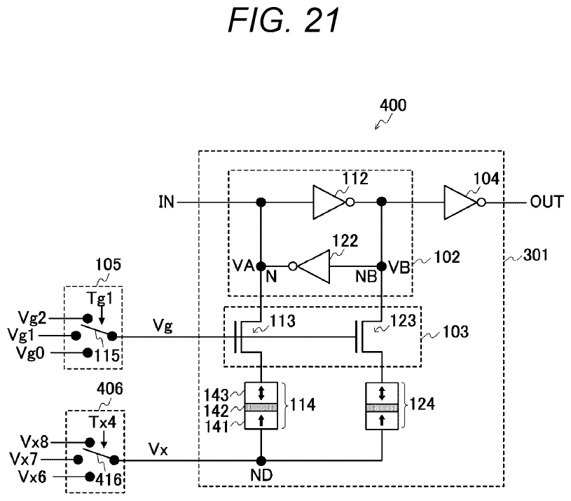

FIG. 21 is a diagram illustrating a configuration example of a storage device according to the fourth embodiment.

In the figure, a storage device 400 includes the gate voltage switching unit 105 and a voltage driver 406 instead of the gate voltage switching unit 205 and the voltage driver 306 of the third embodiment. The configuration of the storage device 400 of the fourth embodiment other than that is similar to the configuration of the storage device 300 of the third embodiment.

A difference between the voltage drivers 306 and 406 is that the drive voltage Vx is switched to the drive voltage V6 at the time of restoring in the voltage driver 306, but the drive voltage Vx is switched to the drive voltage V7 at the time of restoring in the voltage driver 406. At the time of storing, the voltage driver 406 operates similarly to the voltage driver 306. At this time, the voltage driver 406 applies the drive voltage Vx8 to each of the voltage-controlled magneto-resistive effect elements 114 and 124 according to the node voltages VA and VB corresponding to the data held in each of the volatile storage nodes N and NB, and then applies the drive voltage Vx7. However, the voltage driver 306 selects the drive voltage Vx7 at the time of low resistance writing, and selects the drive voltage Vx8 at the time of high resistance writing. The voltage driver 406 selects the drive voltage Vx7 at the time of high resistance writing, and selects the drive voltage Vx8 at the time of low resistance writing.

The voltage driver 406 includes a voltage selector switch 416. The voltage selector switch 416 switches the drive voltages Vx6, Vx7, and Vx8 on the basis of a switching signal Tx4. At this time, the switching signal Tx4 can cause the voltage selector switch 416 to select the drive voltage Vx7 in high resistance writing and select the drive voltage Vx8 in low resistance writing. Furthermore, the switching signal Tx4 can cause the voltage selector switch 416 to select the drive voltage Vx7 at the time of restoring.

Here, in the fourth embodiment, as in the first embodiment, low resistance writing is performed in the first storing operation, and then high resistance writing is performed in the second storing operation. At this time, in the fourth embodiment, as in the first embodiment, the forward logic of the latch circuit 102 is stored in the voltage-controlled magneto-resistive effect elements 114 and 124.

In the case where the data is complementarily restored from the voltage-controlled magneto-resistive effect elements 114 and 124 to the latch circuit 102, the drive voltage Vx7 is applied to the pinned layer 141. At this time, the original data is written back to the latch circuit 102 according to the resistance state of each of the voltage-controlled magneto-resistive effect elements 114 and 124, and the resistance state of each of the voltage-controlled magneto-resistive effect elements 114 and 124 is maintained.

Hereinafter, the latch operation, storing operation, and restoring operation of the storage device 400 will be described. Note that, in the following description, in order to simplify the description, as an example, a case will be taken where the logical value ‘0’ is held in the volatile storage node N and the logical value ‘1’ is held in the volatile storage node NB, and, at that time, the node voltage VA is 0 V and the node voltage VB is 1 V. Furthermore, as an example, a case will be taken where the drive voltage Vx6 is set to 0 V, the drive voltage Vx7 is set to 1 V, and the drive voltage Vx8 is set to 2 V. Note that the node voltages VA and VB and the drive voltages Vx6, Vx7, and Vx8 are not limited to these values.

In the latch operation, as illustrated in FIG. 15, the gate voltage Vg is set to Vg0=0 V. For this reason, the MOS transistors 113 and 123 are turned off, and the latch circuit 102 is disconnected from the voltage-controlled magneto-resistive effect elements 114 and 124.

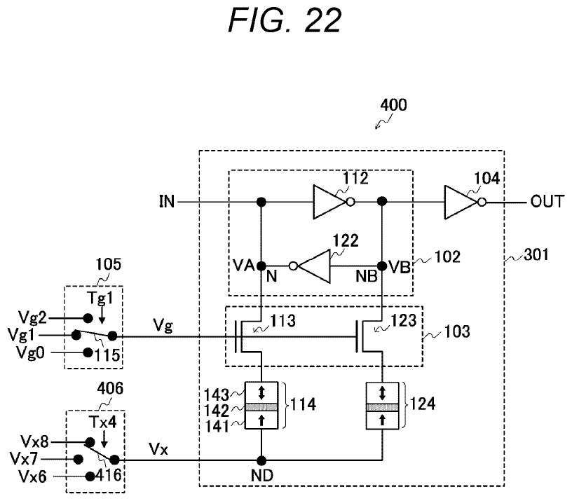

FIG. 22 is a diagram illustrating an example of the first storing operation of the storage device according to the fourth embodiment.

In the figure, in the first storing operation, the gate voltage Vg is set to Vg1, and the drive voltage Vx is set to Vx8=2 V. For this reason, the voltage of 2 V is applied between the volatile storage node N and the drive terminal ND, and the voltage of 1 V is applied between the volatile storage node NB and the drive terminal ND. At this time, the voltage between the volatile storage node NB and the drive terminal ND is divided into a voltage applied to the on-resistance of the MOS transistor 123 and a cell voltage applied to the voltage-controlled magneto-resistive effect element 124. The gate voltage Vg1 is set so that when the voltage between the volatile storage node NB and the drive terminal ND is divided by the on-resistance of the MOS transistor 123, the cell voltage applied to the voltage-controlled magneto-resistive effect element 124 in the high resistance state matches the reversal voltage.

Here, in a case where the voltage-controlled magneto-resistive effect element 124 is in the high resistance state at the time of low resistance writing, since the reversal voltage is applied to the voltage-controlled magneto-resistive effect element 124, the voltage-controlled magneto-resistive effect element 124 transitions from the high resistance state to the low resistance state. On the other hand, in a case where the voltage-controlled magneto-resistive effect element 124 is in the low resistance state at the time of low resistance writing, the voltage division ratio to the on-resistance of the MOS transistor 123 decreases as compared with the case where the voltage-controlled magneto-resistive effect element 124 is in the high resistance state. For this reason, the cell voltage applied to the voltage-controlled magneto-resistive effect element 124 is larger than the reversal voltage, and the low resistance state of the voltage-controlled magneto-resistive effect element 124 is maintained due to the perpendicular magnetic anisotropy of the voltage-controlled magneto-resistive effect element 124.

On the other hand, the voltage of 2 V is applied between the volatile storage node N and the drive terminal ND, and the cell voltage of the voltage-controlled magneto-resistive effect element 114 is larger than the cell voltage of the voltage-controlled magneto-resistive effect element 124. However, for the voltage-controlled magneto-resistive effect element 114, writing is performed in the second storing operation, and thus the resistance state of the voltage-controlled magneto-resistive effect element 114 may be any state.

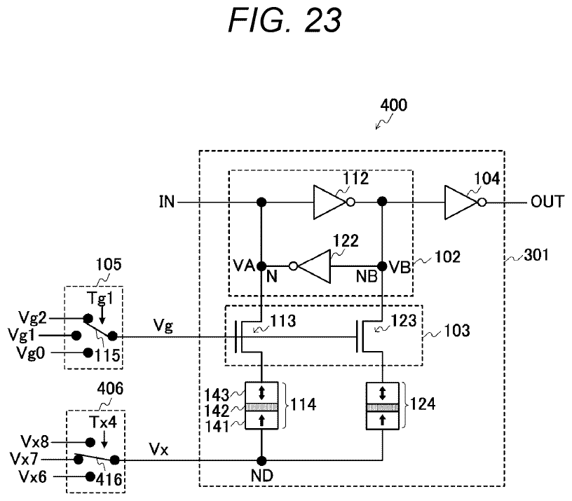

FIG. 23 is a diagram illustrating an example of the second storing operation of the storage device according to the fourth embodiment.

In the figure, in the second storing operation, the gate voltage Vg is set to Vg2, and the drive voltage Vx is set to Vx7=1 V. For this reason, the voltage of 1 V is applied between the volatile storage node N and the drive terminal ND, and the voltage of 0 V is applied between the volatile storage node NB and the drive terminal ND. At this time, the voltage between the volatile storage node N and the drive terminal ND is divided into a voltage applied to the on-resistance of the MOS transistor 113 and a cell voltage applied to the voltage-controlled magneto-resistive effect element 114. Then, the gate voltage Vg2 is set so that when the voltage between the volatile storage node N and the drive terminal ND is divided by the on-resistance of the MOS transistor 113, the cell voltage applied to the voltage-controlled magneto-resistive effect element 114 in the low resistance state matches the reversal voltage.

Here, in a case where the voltage-controlled magneto-resistive effect element 114 is in the low resistance state at the time of high resistance writing, since the reversal voltage is applied to the voltage-controlled magneto-resistive effect element 114, the voltage-controlled magneto-resistive effect element 114 transitions from the low resistance state to the high resistance state. On the other hand, in a case where the voltage-controlled magneto-resistive effect element 114 is in the high resistance state at the time of high resistance writing, the voltage division ratio to the on-resistance of the MOS transistor 113 increases as compared with the case where the voltage-controlled magneto-resistive effect element 114 is in the low resistance state. For this reason, the cell voltage applied to the voltage-controlled magneto-resistive effect element 114 is smaller than the reversal voltage, and an in-plane rotational component appears due to the in-plane magnetic anisotropy of the voltage-controlled magneto-resistive effect element 114, but the rotational component does not contribute to reversal of the magnetization direction, so that the high resistance state of the voltage-controlled magneto-resistive effect element 114 is maintained.

On the other hand, the voltage of 0 V is applied between the volatile storage node NB and the drive terminal ND, and the cell voltage of the voltage-controlled magneto-resistive effect element 124 is 0 V. For this reason, the magnetization direction of the voltage-controlled magneto-resistive effect element 124 does not change, and the low resistance state of the voltage-controlled magneto-resistive effect element 124 is maintained.

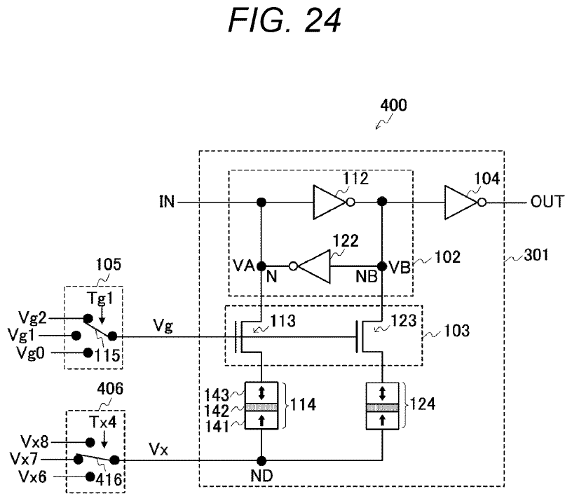

FIG. 24 is a diagram illustrating an example of the restoring operation of the storage device according to the fourth embodiment.

In the figure, in the restoring operation, the gate voltage Vg is set to Vg2, and the drive voltage Vx is set to Vx7=1 V. Here, it is assumed that the voltage-controlled magneto-resistive effect element 114 is in the high resistance state and the voltage-controlled magneto-resistive effect element 124 is in the low resistance state. At this time, the node voltage VA is lower than the node voltage VB, and the logical value ‘0’ is restored in the volatile storage node N and the logical value ‘1’ is restored in the volatile storage node NB.

Here, when the logical value ‘1’ is restored in the volatile storage node NB, the node voltage VB is 1 V, and no voltage is applied to the voltage-controlled magneto-resistive effect element 124, so that the low resistance state of the voltage-controlled magneto-resistive effect element 124 is maintained. On the other hand, when the logical value ‘0’ is restored in the volatile storage node N, the node voltage VA is 0 V, and the voltage of 1 V is applied to the voltage-controlled magneto-resistive effect element 114. At this time, the gate voltage Vg is set to Vg2, and when the voltage-controlled magneto-resistive effect element 114 is in the high resistance state, the high resistance state of the voltage-controlled magneto-resistive effect element 114 is maintained as it is.

Note that, in the description of the first storing operation, the second storing operation, and the restoring operation of the fourth embodiment, as an example, the case has been taken where the logical value ‘0’ is held in the volatile storage node N and the logical value ‘1’ is held in the volatile storage node NB. The first storing operation, the second storing operation, and the restoring operation of the fourth embodiment are similar also in the case where the logical value ‘1’ is held in the volatile storage node N and the logical value ‘0’ is held in the volatile storage node NB.

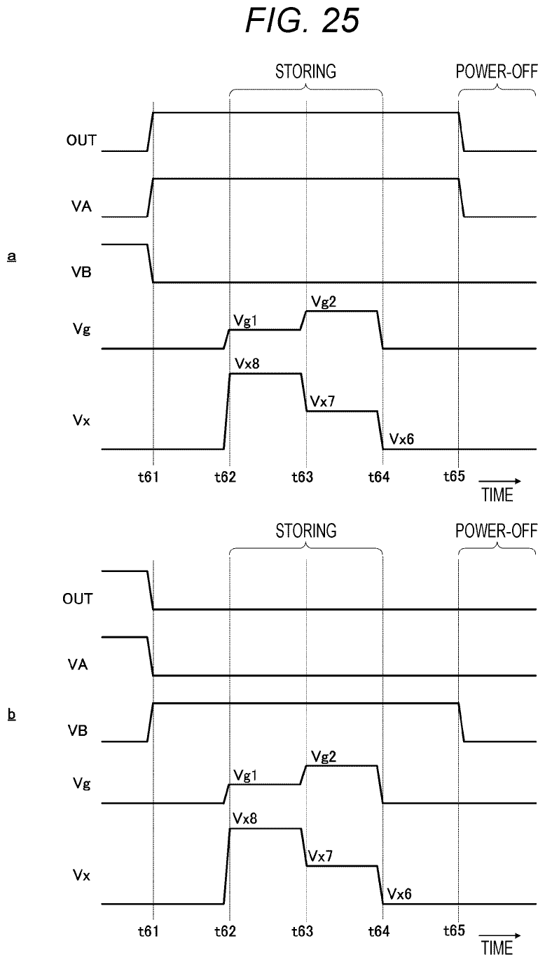

FIG. 25 is a timing chart illustrating an example of the storing timing of the storage device according to the fourth embodiment. Note that, in a of the figure, a voltage waveform is illustrated of each unit at the time of storing in the case where the logical value ‘1’ is held in the volatile storage node N and the logical value ‘0’ is held in the volatile storage node NB. In b of the figure, a voltage waveform is illustrated of each unit at the time of storing in a case where the logical value ‘0’ is held in the volatile storage node N and the logical value ‘1’ is held in the volatile storage node NB.

In a of the figure, it is assumed that the logical value ‘1’ is held in the volatile storage node N, and the logical value ‘0’ is held in the volatile storage node NB. At this time, the node voltage VA is set to 1 V, the node voltage VB is set to 0 V, and the output data OUT is set to the logical value ‘1’ (t61).

Next, the voltage Vg1 is selected as the gate voltage Vg, and the voltage Vx8=2 V is selected as the drive voltage Vx (t62). At this time, the first storing operation is performed, and the voltage-controlled magneto-resistive effect element 114 is set to the low resistance state.

Next, the voltage Vg2 is selected as the gate voltage Vg, and the voltage Vx7=1 V is selected as the drive voltage Vx (t63). At this time, the second storing operation is performed, and the voltage-controlled magneto-resistive effect element 124 is set to the high resistance state.

Next, the voltage Vg0 is selected as the gate voltage Vg (t64). At this time, the voltage-controlled magneto-resistive effect elements 114 and 124 are disconnected from the latch circuit 102.

Next, the storage device 100 is powered off (t65). At this time, the data held in the latch circuit 102 is lost. On the other hand, the voltage-controlled magneto-resistive effect element 114 maintains the low resistance state, and the voltage-controlled magneto-resistive effect element 124 maintains the high resistance state.

In b of the figure, it is assumed that the logical value ‘0’ is held in the volatile storage node N, and the logical value ‘1’ is held in the volatile storage node NB. At this time, the node voltage VA is set to 0 V, the node voltage VB is set to 1 V, and the output data OUT is set to the logical value ‘0’ (t61).

Next, the voltage Vg1 is selected as the gate voltage Vg, and the voltage Vx8=2 V is selected as the drive voltage Vx (t62). At this time, the first storing operation is performed, and the voltage-controlled magneto-resistive effect element 124 is set to the low resistance state.

Next, the voltage Vg1 is selected as the gate voltage Vg, and the voltage Vx7=1 V is selected as the drive voltage Vx (t63). At this time, the second storing operation is performed, and the voltage-controlled magneto-resistive effect element 114 is set to the high resistance state.

Next, the voltage Vg0 is selected as the gate voltage Vg (t64). At this time, the voltage-controlled magneto-resistive effect elements 114 and 124 are disconnected from the latch circuit 102.

Next, the storage device 100 is powered off (t65). At this time, the data held in the latch circuit 102 is lost. On the other hand, the voltage-controlled magneto-resistive effect element 114 maintains the high resistance state, and the voltage-controlled magneto-resistive effect element 124 maintains the low resistance state.

As described above, in the storing operation of the storage device 400, regardless of whether the output data OUT from the latch circuit 102 is the logical value ‘0’ or the logical value ‘1’, low resistance writing is performed in the first storing operation, and high resistance writing is performed in the second storing operation.

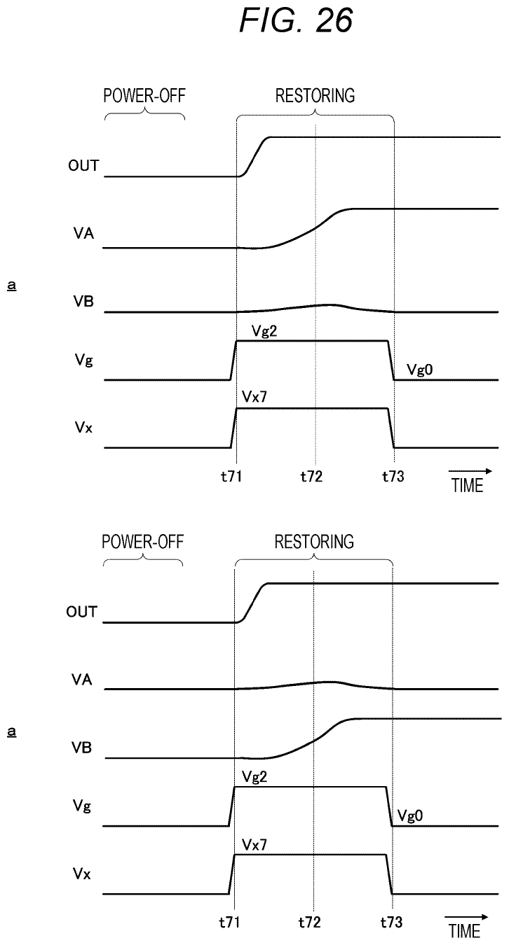

FIG. 26 is a timing chart illustrating an example of the restoring timing of the storage device according to the fourth embodiment. Note that, in a of the figure, a voltage waveform is illustrated of each unit when the logical value ‘1’ is restored in the volatile storage node N and the logical value ‘0’ is restored in the volatile storage node NB. In b of the figure, a voltage waveform is illustrated of each unit at the time of restoring the logical value ‘0’ in the volatile storage node N and the logical value ‘1’ in the volatile storage node NB.

In a of the figure, it is assumed that charge of the latch circuit 102 is discharged by power-off of the storage device 300 after the storing to the voltage-controlled magneto-resistive effect elements 114 and 124. At this time, it is assumed that the voltage-controlled magneto-resistive effect element 114 holds the low resistance state, and the voltage-controlled magneto-resistive effect element 124 holds the high resistance state.

Here, at the time of restoring, the voltage Vg2 is selected as the gate voltage Vg, and the voltage Vx7=1 V is selected as the drive voltage Vx (t71). At this time, the node voltage VA is higher than the node voltage VB (t72), and the logical value ‘1’ is restored in the volatile storage node N and the logical value ‘0’ is restored in the volatile storage node NB.

Next, the voltage Vg0 is selected as the gate voltage Vg (t73). At this time, the voltage-controlled magneto-resistive effect elements 114 and 124 are disconnected from the latch circuit 102. Furthermore, the voltage-controlled magneto-resistive effect element 114 maintains the low resistance state, and the voltage-controlled magneto-resistive effect element 124 maintains the high resistance state.

In b of the figure, it is assumed that the voltage-controlled magneto-resistive effect element 114 holds the high resistance state, and the voltage-controlled magneto-resistive effect element 124 holds the low resistance state.

Here, at the time of restoring, the voltage Vg2 is selected as the gate voltage Vg, and the voltage Vx7=1 V is selected as the drive voltage Vx (t71). At this time, the node voltage VA is lower than the node voltage VB (t72), and the logical value ‘0’ is restored in the volatile storage node N and the logical value ‘1’ is restored in the volatile storage node NB.

Next, the voltage Vg0 is selected as the gate voltage Vg (t73). At this time, the voltage-controlled magneto-resistive effect elements 114 and 124 are disconnected from the latch circuit 102. Furthermore, the voltage-controlled magneto-resistive effect element 114 maintains the high resistance state, and the voltage-controlled magneto-resistive effect element 124 maintains the low resistance state.

As described above, in the fourth embodiment, in a case where data is stored from the latch circuit 102 to each of the voltage-controlled magneto-resistive effect elements 114 and 124, when the gate voltage Vg1 is applied to each of the MOS transistors 113 and 123, the drive voltage Vx8 is applied to the pinned layer 141 of each of the voltage-controlled magneto-resistive effect elements 114 and 124. Thereafter, when the gate voltage Vg2 is applied to each of the MOS transistors 113 and 123, the drive voltage Vx7 is applied to the pinned layer 141 of each of the voltage-controlled magneto-resistive effect elements 114 and 124.

As a result, without destroying the low resistance state at the time of low resistance writing for one of the voltage-controlled magneto-resistive effect elements 114 and 124, after the low resistance writing, it is possible to perform high resistance writing for the other of the voltage-controlled magneto-resistive effect elements 114 and 124. For this reason, the logical value ‘0’ of the latch circuit 102 can be held as the low resistance state in one of the voltage-controlled magneto-resistive effect elements 114 and 124, and the logical value ‘1’ of the latch circuit 102 can be held as the high resistance state in the other of the voltage-controlled magneto-resistive effect elements 114 and 124. At this time, in order to store data from the latch circuit 102 to each of the voltage-controlled magneto-resistive effect elements 114 and 124, it is only required to set the drive voltages Vx7 and Vx8 to positive voltages, and it is possible to make a negative voltage unnecessary.

Furthermore, in a case where the data is restored from each of the voltage-controlled magneto-resistive effect elements 114 and 124 to the latch circuit 102, the voltage higher than the voltage applied to the free layer 143 of each of the voltage-controlled magneto-resistive effect elements 114 and 124 is applied to the pinned layer 141. As a result, it is possible to restore the data from each of the voltage-controlled magneto-resistive effect elements 114 and 124 to the latch circuit 102 without destroying the data held in each of the voltage-controlled magneto-resistive effect elements 114 and 124.

### 5. Fifth Embodiment

In the first embodiment, the voltage-controlled magneto-resistive effect elements 114 and 124 are provided in the latch circuit 102. In this fifth embodiment, the voltage-controlled magneto-resistive effect elements 114 and 124 are provided in a flip-flop.

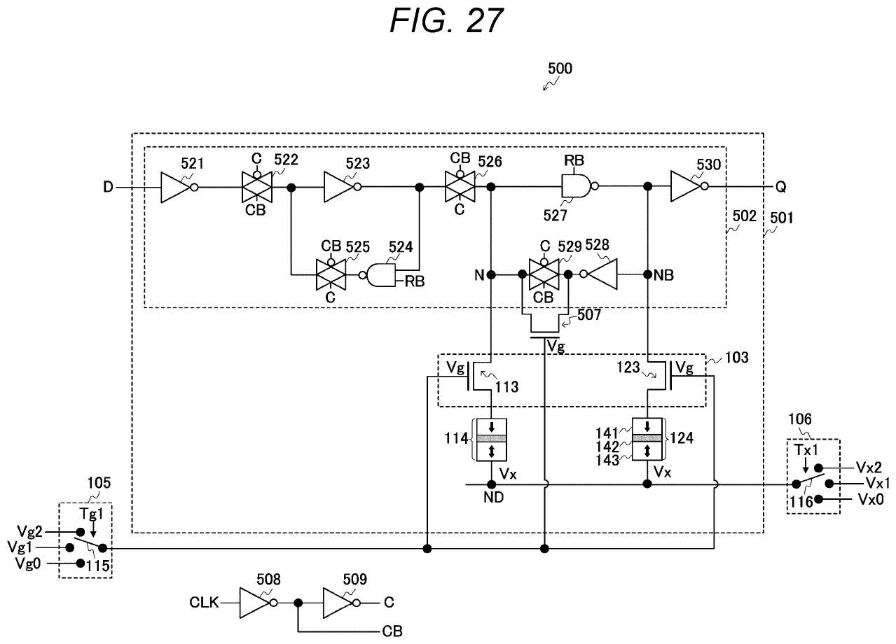

FIG. 27 is a diagram illustrating a configuration example of a storage device according to the fifth embodiment. Note that, in the fifth embodiment, an example will be described in which a flip-flop is provided instead of the latch circuit 102 of the first embodiment.

In the figure, a storage device 500 includes a flip flop (FF) cell 501 instead of the latch cell 101 of the first embodiment. The configuration of the storage device 500 of the fifth embodiment other than that is similar to the configuration of the storage device 100 of the first embodiment.

The FF cell 501 includes a flip-flop 502 instead of the latch circuit 102 of the first embodiment. Note that the flip-flop 502 is an example of the volatile storage unit described in the claims.

The flip-flop 502 complementarily holds data. At this time, the flip-flop 502 operates as a bistable circuit and can hold the data in a volatile manner. The flip-flop 502 includes the volatile storage nodes N and NB that complementarily hold the data. Each of the volatile storage nodes N and NB holds the data in a volatile manner. At this time, the flip-flop 502 complementarily holds a logical value corresponding to input data D in each of the volatile storage nodes N and NB, and outputs the logical value as output data Q.

The flip-flop 502 includes inverters 521, 523, 528, and 530, NAND circuits 524 and 527, and transfer gates 522, 525, 526, and 529.

The inverter 521, the transfer gate 522, the inverter 523, the transfer gate 526, the NAND circuit 524, and the inverter 530 are connected together in series sequentially. The input data D is input to the inverter 521. The output data Q is output from the inverter 530.

Furthermore, the output of the inverter 523 is input to the NAND circuit 524, and the output of the NAND circuit 524 is input to the inverter 523 via the transfer gate 525. The output of the NAND circuit 524 is input to the inverter 528, and the output of the inverter 528 is input to the NAND circuit 527 via the transfer gate 529. Furthermore, a reset signal RB is input to each of the NAND circuits 524 and 527.

Furthermore, a non-inverted clock signal C is input to the inverting input of each of the transfer gates 522 and 529 and the non-inverting input of each of the transfer gates 525 and 526. An inverted clock signal CB is input to the non-inverting input of each of the transfer gates 522 and 529 and the inverting input of each of the transfer gates 525 and 526. The inverted clock signal CB can be generated by inversion of a clock signal CLK via the inverter 508. The non-inverted clock signal C can be generated by twice inversion of the clock signal CLK via the inverters 508 and 509 in sequence. A reset transistor 507 is connected in parallel to the transfer gate 529. The reset transistor 507 may be a MOS transistor.

The voltage-controlled magneto-resistive effect element 114 is connected to the volatile storage node N of the flip-flop 502 via the MOS transistor 113. The voltage-controlled magneto-resistive effect element 124 is connected to the volatile storage node NB of the flip-flop 502 via the MOS transistor 123. The free layer 143 of each of the voltage-controlled magneto-resistive effect elements 114 and 124 is connected to the drive terminal ND. The drive voltage Vx is applied from the voltage driver 106 to the drive terminal ND. The gate voltage Vg is applied from the gate voltage switching unit 105 to the gates of the MOS transistors 113 and 123 and the gate of the reset transistor 507.

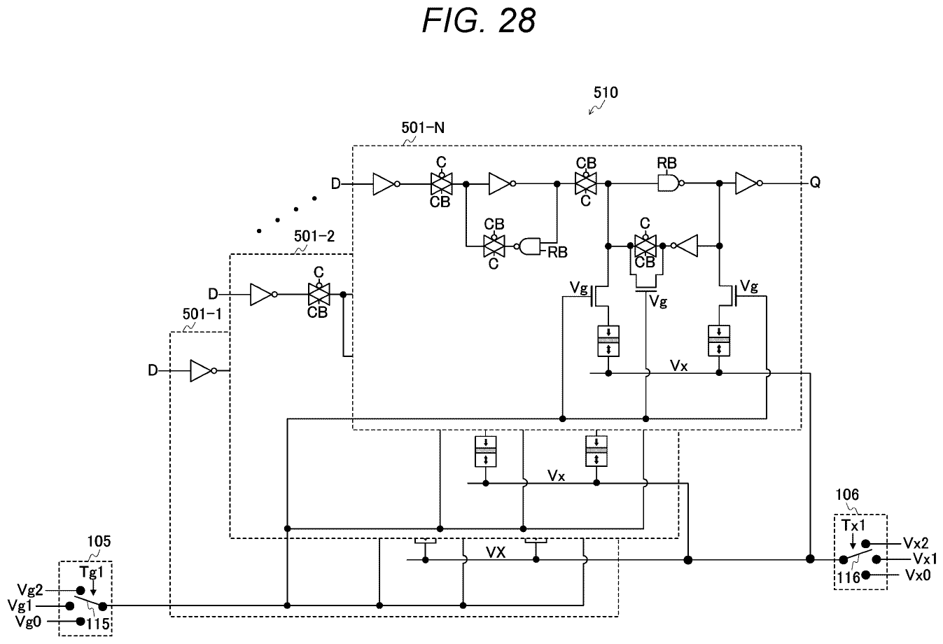

FIG. 28 is a diagram illustrating a modification of the storage device according to the fifth embodiment.

In the figure, a storage device 510 includes a plurality of FF cells 501-1 to 501-N (N is an integer greater than or equal to 2), the gate voltage switching unit 105, and the voltage driver 106. Each of the FF cells 501-1 to 501-N can be configured similarly to the FF cell 501. The gate voltage switching unit 105 supplies the gate voltage Vg to the plurality of FF cells 501-1 to 501-N. The voltage driver 106 supplies the drive voltage Vx to the plurality of FF cells 501-1 to 501-N.

As described above, in the fifth embodiment, the voltage-controlled magneto-resistive effect elements 114 and 124 are provided in the flip-flop 502. As a result, it is possible to add a nonvolatile storage function to the flip-flop 502 while suppressing an increase in power consumption when the data held in the flip-flop 502 is stored in the voltage-controlled magneto-resistive effect elements 114 and 124.

Note that, in the fifth embodiment, an example has been described in which the flip-flop 502 is provided instead of the latch circuit 102 of the first embodiment; however, the flip-flop 502 may be provided instead of the latch circuit 102 of the second embodiment. Furthermore, the flip-flop 502 may be provided instead of the latch circuit 102 of the third embodiment, or the flip-flop 502 may be provided instead of the latch circuit 102 of the fourth embodiment.

### 6. Sixth Embodiment

In the first embodiment, the voltage-controlled magneto-resistive effect elements 114 and 124 are provided in the latch circuit 102. In this sixth embodiment, the voltage-controlled magneto-resistive effect elements 114 and 124 are provided in an SRAM.

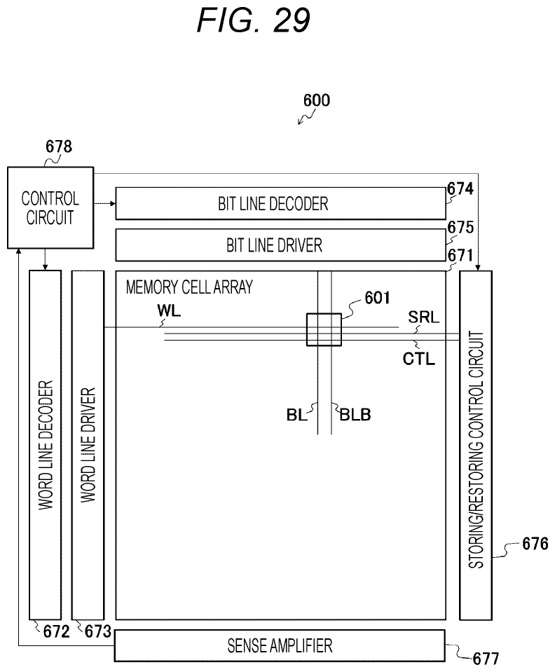

FIG. 29 is a diagram illustrating a configuration example of a storage device according to the sixth embodiment.

In the figure, a storage device 600 includes a memory cell array 671, a word line decoder 672, a word line driver 673, a bit line decoder 674, and a bit line driver 675. Furthermore, the storage device 600 includes a storing/restoring control circuit 676, a sense amplifier 677, and a control circuit 678.

In the memory cell array 671, memory cells 601 are arranged in a matrix in the row direction and the column direction. Each memory cell 601 is provided with a volatile storage unit and a nonvolatile storage unit. The SRAM is provided as the volatile storage unit. The voltage-controlled magneto-resistive effect elements 114 and 124 are provided as the nonvolatile storage unit. The MOS transistors 113 and 123 are connected between the SRAM and the voltage-controlled magneto-resistive effect elements 114 and 124, respectively. At this time, each memory cell 601 can constitute a non-volatile (NV) SRAM. Furthermore, in the memory cell array 671, a word line WL is provided for each row, and bit lines BL and BLB are provided for each column. Moreover, the memory cell array 671 is provided with a voltage switching line SRL and a voltage drive line CTL. The voltage switching line SRL supplies a voltage used for setting the resistance state of the voltage-controlled magneto-resistive effect elements 114 and 124 to each of the MOS transistors 113 and 123. The voltage drive line CTL supplies a drive voltage used at the time of storing and the time of restoring to each of the voltage-controlled magneto-resistive effect elements 114 and 124. Note that, in the following description, writing of data to the SRAM is referred to as writing, and reading of data from the SRAM is referred to as reading.

The word line decoder 672 interprets a command and a row address, and selects the word line WL to which a memory cell 601 to be a target of reading or writing is connected. The word line driver 673 drives the word line WL selected by the word line decoder 672.

The bit line decoder 674 interprets the command and the row address, and selects the bit lines BL and BLB to which a memory cell 601 to be a target of reading or writing is connected. The bit line driver 675 drives the bit lines BL and BLB selected by the bit line decoder 674.

The storing/restoring control circuit 676 controls storing and restoring for the memory cells 601 included in the memory cell array 671. At this time, the storing/restoring control circuit 676 applies, to the voltage switching line SRL, the voltage used for setting the resistance state of the voltage-controlled magneto-resistive effect elements 114 and 124 at the time of storing. Furthermore, the storing/restoring control circuit 676 applies the drive voltage used at the time of storing and the time of restoring to the voltage drive line CTL.

The sense amplifier 677 detects data read from the memory cell array 671 on the basis of potentials of the bit lines BL and BLB selected by the bit line decoder 674. The control circuit 678 receives, as an input, the data detected by the sense amplifier 677 and controls operation of the bit line decoder 674, the word line decoder 672, and the storing/restoring control circuit 676.

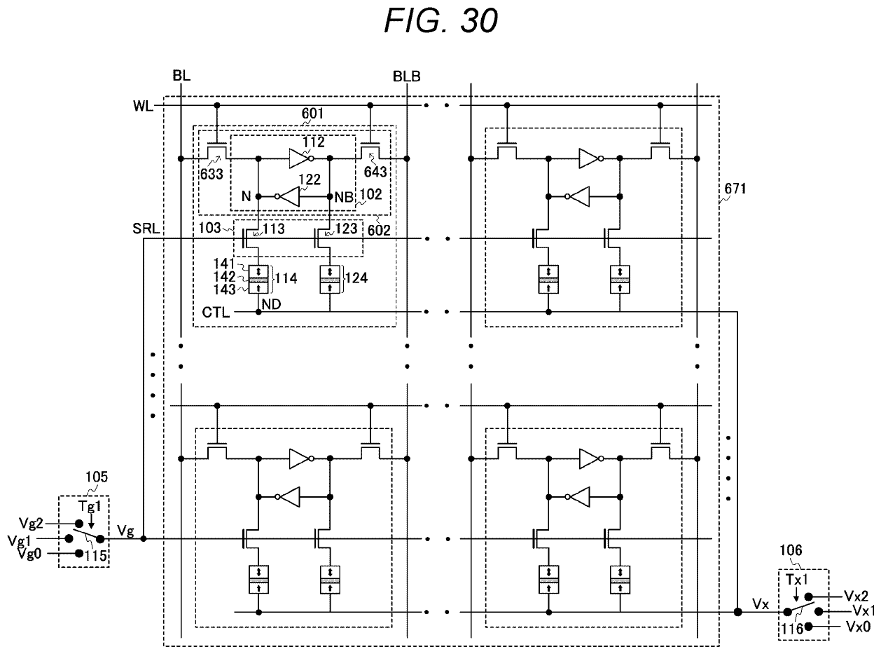

FIG. 30 is a diagram illustrating a configuration example of the memory cell of the storage device according to the sixth embodiment.

In the figure, the memory cell 601 includes an SRAM 602 instead of the latch circuit 102 of the first embodiment. Note that the SRAM 602 is an example of the volatile storage unit described in the claims.

The SRAM 602 complementarily holds data. At this time, the SRAM 602 operates as a bistable circuit and can hold the data in a volatile manner. The SRAM 602 includes the volatile storage nodes N and NB that complementarily hold the data. Each of the volatile storage nodes N and NB holds the data in a volatile manner.

In the SRAM 602, access transistors 633 and 643 are added to the latch circuit 102. The access transistors 633 and 643 may be MOS transistors. The access transistor 633 is connected between the bit line BL and the volatile storage node N. The access transistor 643 is connected between the bit line BLB and the volatile storage node NB. The gates of the access transistors 633 and 643 are connected to the word line WL.

The voltage-controlled magneto-resistive effect element 114 is connected to the volatile storage node N of the SRAM 602 via the MOS transistor 113. The voltage-controlled magneto-resistive effect element 124 is connected to the volatile storage node NB of the SRAM 602 via the MOS transistor 123. The free layer 143 of each of the voltage-controlled magneto-resistive effect elements 114 and 124 is connected to the drive terminal ND. The drive voltage Vx is applied from the voltage driver 106 to the drive terminal ND via the voltage drive line CTL. The gate voltage Vg is applied from the gate voltage switching unit 105 to the gates of the MOS transistors 113 and 123 via the voltage switching line SRL.

As described above, in the sixth embodiment, the voltage-controlled magneto-resistive effect elements 114 and 124 are provided in each memory cell 601 including the SRAM 602. As a result, it is possible to add a nonvolatile storage function to the SRAM while suppressing an increase in power consumption when the data held in the SRAM is stored in the voltage-controlled magneto-resistive effect elements 114 and 124.

Note that, in the sixth embodiment, an example has been shown in which the SRAM 602 is provided instead of the latch circuit 102 of the first embodiment; however, the SRAM 602 may be provided instead of the latch circuit 102 of the second embodiment. Furthermore, the SRAM 602 may be provided instead of the latch circuit 102 of the third embodiment, or the SRAM 602 may be provided instead of the latch circuit 102 of the fourth embodiment.

Note that the embodiments described above show an example for embodying the present technology, and the matters in the embodiments and the matters specifying the invention in the claims have a correspondence relationship. Similarly, the matters specifying the invention in the claims and the matters with the same names in the embodiments of the present technology have correspondence relationships, respectively. However, the present technology is not limited to the embodiments, and can be embodied by making various modifications to the embodiments without departing from the scope of the present technology. Furthermore, effects described in the present specification are merely examples and are not limited, and other effects may be provided.

Note that the present technology may also have the following configurations.
(1) A storage device including:
a volatile storage unit that complementarily holds data; and
a voltage-controlled magneto-resistive effect element that holds the data complementarily held in the volatile storage unit.
(2) The storage device according to (1), further including
a variable resistance element connected between the volatile storage unit and the voltage-controlled magneto-resistive effect element, the variable resistance element enabling resistance between the volatile storage unit and the voltage-controlled magneto-resistive effect element to vary.
(3) The storage device according to (2), in which
the variable resistance element varies resistance to cause cell voltages applied to the voltage-controlled magneto-resistive effect element to be substantially equal to each other, the cell voltages being a cell voltage applied when the voltage-controlled magneto-resistive effect element transitions from a high resistance state to a low resistance state and a cell voltage applied when the voltage-controlled magneto-resistive effect element transitions from the low resistance state to the high resistance state.
(4) The storage device according to (2) or (3), in which
the variable resistance element is a field effect transistor whose on-resistance varies on the basis of a gate voltage.
(5) The storage device according to (4), in which
the field effect transistor is used not only as the variable resistance element but also as a storing transistor that stores data from the volatile storage unit to the voltage-controlled magneto-resistive effect element and a restoring transistor that restores the data from the voltage-controlled magneto-resistive effect element to the volatile storage unit.
(6) The storage device according to (4), further including
a gate voltage switching unit that switches between a first gate voltage applied to the field effect transistor in a case where low resistance writing is performed for the voltage-controlled magneto-resistive effect element and a second gate voltage applied to the field effect transistor in a case where high resistance writing is performed for the voltage-controlled magneto-resistive effect element.
(7) The storage device according to (6), in which
in a case where the voltage-controlled magneto-resistive effect element is in a high resistance state in the case where low resistance writing is performed, a reversal voltage that reverses a magnetization direction of the voltage-controlled magneto-resistive effect element is applied to the voltage-controlled magneto-resistive effect element on the basis of the first gate voltage;
in a case where the voltage-controlled magneto-resistive effect element is in a low resistance state in the case where low resistance writing is performed, a voltage smaller than the reversal voltage is applied to the voltage-controlled magneto-resistive effect element on the basis of the first gate voltage;
in a case where the voltage-controlled magneto-resistive effect element is in the low resistance state in the case where high resistance writing is performed, the reversal voltage is applied to the voltage-controlled magneto-resistive effect element on the basis of the second gate voltage; and
in a case where the voltage-controlled magneto-resistive effect element is in the high resistance state in the case where high resistance writing is performed, a voltage larger than the reversal voltage is applied to the voltage-controlled magneto-resistive effect element on the basis of the second gate voltage.
(8) The storage device according to (6) or (7), further including a voltage driver that applies a reversal voltage that reverses a magnetization direction of the voltage-controlled magneto-resistive effect element on the basis of a voltage controlled magnetic anisotropy (VCMA) effect.
(9) The storage device according to (8), in which
in the voltage-controlled magneto-resistive effect element, a low resistance state and a high resistance state according to the data complementarily held in the volatile storage unit are each stored on the basis of stepwise change in voltage having an identical polarity applied to the voltage-controlled magneto-resistive effect element.
(10) The storage device according to (8) or (9), in which
the voltage-controlled magneto-resistive effect element includes a first voltage-controlled magneto-resistive effect element and a second voltage-controlled magneto-resistive effect element in which resistance states different from each other are set in accordance with the data complementarily held in the volatile storage unit,
the voltage driver applies, to the first voltage-controlled magneto-resistive effect element and the second voltage-controlled magneto-resistive effect element, a first drive voltage and then a second drive voltage in accordance with node voltages corresponding to the data complementarily held in the volatile storage unit,
the first drive voltage is set to cause a reversal voltage to be applied to the first voltage-controlled magneto-resistive effect element and perpendicular magnetic anisotropy of the second voltage-controlled magneto-resistive effect element to be increased, and
the second drive voltage is set to cause a reversal voltage to be applied to the second voltage-controlled magneto-resistive effect element, and a voltage smaller than the reversal voltage to be applied to the first voltage-controlled magneto-resistive effect element.
(11) The storage device according to (10), in which
when the reversal voltage is applied to the first voltage-controlled magneto-resistive effect element, a voltage higher than the reversal voltage by a difference between the node voltages is applied to the second voltage-controlled magneto-resistive effect element, and
when the reversal voltage is applied to the second voltage-controlled magneto-resistive effect element, a voltage lower than the reversal voltage by the difference between the node voltages is applied to the first voltage-controlled magneto-resistive effect element.
(12) The storage device according to (10) or (11), in which
the voltage smaller than the reversal voltage is 0 V.
(13) The storage device according to any of (10) to (12), in which
the voltage-controlled magneto-resistive effect element includes:
a pinned layer in which a magnetization direction is fixed;
a free layer in which a magnetization direction of magnetism induced on the basis of a voltage is reversible; and
a tunnel barrier layer sandwiched between the pinned layer and the free layer.
(14) The storage device according to (13), in which
in a case where data is stored from the volatile storage unit to the voltage-controlled magneto-resistive effect element,
the first drive voltage is applied to the free layer of the voltage-controlled magneto-resistive effect element when the first gate voltage is applied to the field effect transistor, and then
the second drive voltage is applied to the free layer of the voltage-controlled magneto-resistive effect element when the second gate voltage is applied to the field effect transistor, and
in a case where the data is restored from the voltage-controlled magneto-resistive effect element to the volatile storage unit,
a voltage lower than a voltage applied to the pinned layer is applied to the free layer.
(15) The storage device according to (13), in which
in a case where data is stored from the volatile storage unit to the voltage-controlled magneto-resistive effect element,
the first drive voltage is applied to the free layer of the voltage-controlled magneto-resistive effect element when the second gate voltage is applied to the field effect transistor, and then
the second drive voltage is applied to the free layer of the voltage-controlled magneto-resistive effect element when the first gate voltage is applied to the field effect transistor, and
in a case where the data is restored from the voltage-controlled magneto-resistive effect element to the volatile storage unit,
a voltage higher than a voltage applied to the pinned layer is applied to the free layer.
(16) The storage device according to (13), in which
in a case where data is stored from the volatile storage unit to the voltage-controlled magneto-resistive effect element,
the first drive voltage is applied to the pinned layer of the voltage-controlled magneto-resistive effect element when the second gate voltage is applied to the field effect transistor, and then
the second drive voltage is applied to the pinned layer of the voltage-controlled magneto-resistive effect element when the first gate voltage is applied to the field effect transistor, and
in a case where the data is restored from the voltage-controlled magneto-resistive effect element to the volatile storage unit,
a voltage lower than a voltage applied to the free layer is applied to the pinned layer.
(17) The storage device according to (13), in which
in a case where data is stored from the volatile storage unit to the voltage-controlled magneto-resistive effect element,
the first drive voltage is applied to the pinned layer of the voltage-controlled magneto-resistive effect element when the first gate voltage is applied to the field effect transistor, and then
the second drive voltage is applied to the pinned layer of the voltage-controlled magneto-resistive effect element when the second gate voltage is applied to the field effect transistor, and
in a case where the data is restored from the voltage-controlled magneto-resistive effect element to the volatile storage unit,
a voltage higher than a voltage applied to the free layer is applied to the pinned layer.
(18) The storage device according to any of (1) to (17), in which the volatile storage unit is a latch circuit.
(19) The storage device according to any of (1) to (17), in which the volatile storage unit is a flip-flop.
(20) The storage device according to any of (1) to (17), in which the volatile storage unit is a static random access memory (SRAM).

### REFERENCE SIGNS LIST

100 to 600 Storage device
101 Latch cell
102 Latch circuit
112, 122 Inverter
103 Variable resistance circuit
113, 123 MOS transistor
114, 124 Voltage-controlled magneto-resistive effect element
141 Pinned layer
142 Tunnel barrier layer
143 Free layer
105 Gate voltage switching unit
115 Resistance control switch
106 Voltage driver
116 Voltage selector switch

1. A storage device comprising:
a volatile storage unit that complementarily holds data; and
a voltage-controlled magneto-resistive effect element that holds the data complementarily held in the volatile storage unit.

2. The storage device according to claim 1, further comprising
a variable resistance element connected between the volatile storage unit and the voltage-controlled magneto-resistive effect element, the variable resistance element enabling resistance between the volatile storage unit and the voltage-controlled magneto-resistive effect element to vary.

3. The storage device according to claim 2, wherein
the variable resistance element varies resistance to cause cell voltages applied to the voltage-controlled magneto-resistive effect element to be substantially equal to each other, the cell voltages being a cell voltage applied when the voltage-controlled magneto-resistive effect element transitions from a high resistance state to a low resistance state and a cell voltage applied when the voltage-controlled magneto-resistive effect element transitions from the low resistance state to the high resistance state.

4. The storage device according to claim 2, wherein
the variable resistance element is a field effect transistor whose on-resistance varies on a basis of a gate voltage.

5. The storage device according to claim 4, wherein
the field effect transistor is used not only as the variable resistance element but also as a storing transistor that stores data from the volatile storage unit to the voltage-controlled magneto-resistive effect element and a restoring transistor that restores the data from the voltage-controlled magneto-resistive effect element to the volatile storage unit.

6. The storage device according to claim 4, further comprising
a gate voltage switching unit that switches between a first gate voltage applied to the field effect transistor in a case where low resistance writing is performed for the voltage-controlled magneto-resistive effect element and a second gate voltage applied to the field effect transistor in a case where high resistance writing is performed for the voltage-controlled magneto-resistive effect element.

7. The storage device according to claim 6, wherein
in a case where the voltage-controlled magneto-resistive effect element is in a high resistance state in the case where low resistance writing is performed, a reversal voltage that reverses a magnetization direction of the voltage-controlled magneto-resistive effect element is applied to the voltage-controlled magneto-resistive effect element on a basis of the first gate voltage;
in a case where the voltage-controlled magneto-resistive effect element is in a low resistance state in the case where low resistance writing is performed, a voltage smaller than the reversal voltage is applied to the voltage-controlled magneto-resistive effect element on the basis of the first gate voltage;
in a case where the voltage-controlled magneto-resistive effect element is in the low resistance state in the case where high resistance writing is performed, the reversal voltage is applied to the voltage-controlled magneto-resistive effect element on a basis of the second gate voltage; and
in a case where the voltage-controlled magneto-resistive effect element is in the high resistance state in the case where high resistance writing is performed, a voltage larger than the reversal voltage is applied to the voltage-controlled magneto-resistive effect element on the basis of the second gate voltage.

8. The storage device according to claim 6, further comprising a voltage driver that applies a reversal voltage that reverses a magnetization direction of the voltage-controlled magneto-resistive effect element on a basis of a voltage controlled magnetic anisotropy (VCMA) effect.

9. The storage device according to claim 8, wherein
in the voltage-controlled magneto-resistive effect element, a low resistance state and a high resistance state according to the data complementarily held in the volatile storage unit are each stored on a basis of stepwise change in voltage having an identical polarity applied to the voltage-controlled magneto-resistive effect element.

10. The storage device according to claim 8, wherein
the voltage-controlled magneto-resistive effect element includes a first voltage-controlled magneto-resistive effect element and a second voltage-controlled magneto-resistive effect element in which resistance states different from each other are set in accordance with the data complementarily held in the volatile storage unit,
the voltage driver applies, to the first voltage-controlled magneto-resistive effect element and the second voltage-controlled magneto-resistive effect element, a first drive voltage and then a second drive voltage in accordance with node voltages corresponding to the data complementarily held in the volatile storage unit,
the first drive voltage is set to cause a reversal voltage to be applied to the first voltage-controlled magneto-resistive effect element and perpendicular magnetic anisotropy of the second voltage-controlled magneto-resistive effect element to be increased, and
the second drive voltage is set to cause a reversal voltage to be applied to the second voltage-controlled magneto-resistive effect element, and a voltage smaller than the reversal voltage to be applied to the first voltage-controlled magneto-resistive effect element.

11. The storage device according to claim 10, wherein
when the reversal voltage is applied to the first voltage-controlled magneto-resistive effect element, a voltage higher than the reversal voltage by a difference between the node voltages is applied to the second voltage-controlled magneto-resistive effect element, and
when the reversal voltage is applied to the second voltage-controlled magneto-resistive effect element, a voltage lower than the reversal voltage by the difference between the node voltages is applied to the first voltage-controlled magneto-resistive effect element.

12. The storage device according to claim 10, wherein
the voltage smaller than the reversal voltage is 0 V.

13. The storage device according to claim 10, wherein
the voltage-controlled magneto-resistive effect element includes:
a pinned layer in which a magnetization direction is fixed;
a free layer in which a magnetization direction of magnetism induced on a basis of a voltage is reversible; and
a tunnel barrier layer sandwiched between the pinned layer and the free layer.

14. The storage device according to claim 13, wherein
in a case where data is stored from the volatile storage unit to the voltage-controlled magneto-resistive effect element,
the first drive voltage is applied to the free layer of the voltage-controlled magneto-resistive effect element when the first gate voltage is applied to the field effect transistor, and then
the second drive voltage is applied to the free layer of the voltage-controlled magneto-resistive effect element when the second gate voltage is applied to the field effect transistor, and
in a case where the data is restored from the voltage-controlled magneto-resistive effect element to the volatile storage unit,
a voltage lower than a voltage applied to the pinned layer is applied to the free layer.

15. The storage device according to claim 13, wherein
in a case where data is stored from the volatile storage unit to the voltage-controlled magneto-resistive effect element,
the first drive voltage is applied to the free layer of the voltage-controlled magneto-resistive effect element when the second gate voltage is applied to the field effect transistor, and then
the second drive voltage is applied to the free layer of the voltage-controlled magneto-resistive effect element when the first gate voltage is applied to the field effect transistor, and
in a case where the data is restored from the voltage-controlled magneto-resistive effect element to the volatile storage unit,
a voltage higher than a voltage applied to the pinned layer is applied to the free layer.

16. The storage device according to claim 13, wherein
in a case where data is stored from the volatile storage unit to the voltage-controlled magneto-resistive effect element,
the first drive voltage is applied to the pinned layer of the voltage-controlled magneto-resistive effect element when the second gate voltage is applied to the field effect transistor, and then
the second drive voltage is applied to the pinned layer of the voltage-controlled magneto-resistive effect element when the first gate voltage is applied to the field effect transistor, and
in a case where the data is restored from the voltage-controlled magneto-resistive effect element to the volatile storage unit,
a voltage lower than a voltage applied to the free layer is applied to the pinned layer.

17. The storage device according to claim 13, wherein
in a case where data is stored from the volatile storage unit to the voltage-controlled magneto-resistive effect element,
the first drive voltage is applied to the pinned layer of the voltage-controlled magneto-resistive effect element when the first gate voltage is applied to the field effect transistor, and then
the second drive voltage is applied to the pinned layer of the voltage-controlled magneto-resistive effect element when the second gate voltage is applied to the field effect transistor, and
in a case where the data is restored from the voltage-controlled magneto-resistive effect element to the volatile storage unit,
a voltage higher than a voltage applied to the free layer is applied to the pinned layer.

18. The storage device according to claim 1, wherein the volatile storage unit is a latch circuit.

19. The storage device according to claim 1, wherein the volatile storage unit is a flip-flop.

20. The storage device according to claim 1, wherein the volatile storage unit is a static random access memory (SRAM).
